(19) United States
(12) Patent Application Publication
(10) Pub. No.: US 2025/0066900 A1
(43) Pub. Date: Feb. 27, 2025

(54) METAL/METAL OXIDE DECORATED POLYMER SUBSTRATE-BASED MULTIFUNCTIONAL NANOCOMPOSITES

(71) Applicant: KING FAHD UNIVERSITY OF PETROLEUM AND MINERALS, Dhahran (SA)

(72) Inventor: Mohammad Kamal HOSSAIN, Dhahran (SA)

(73) Assignee: KING FAHD UNIVERSITY OF PETROLEUM AND MINERALS, Dhahran (SA)

(21) Appl. No.: 18/453,737

(22) Filed: Aug. 22, 2023

(51) Int. Cl. C23C 14/20; C08J 7/06; C23C 14/00

(52) U.S. Cl. CPC C23C 14/20; C08J 7/06; C23C 14/0036; C08J 2369/00

(57) ABSTRACT

An Ag or WO₃ nanoparticle decorated polymer substrate includes a treated polycarbonate (PC) substrate. The treated PC substrate has a roughened surface including polycarbonate structures in the form of circular shaped base structures covering a surface of the treated PC substrate, and nano-flowers directly grown on the circular shaped base structures. The nano-flowers have elongated petals extending therefrom. The circular shaped base structures have an average diameter of 2 to 10 micrometers (μm). The average width of the elongated petals of the nano-flowers is in a range of 60 to 400 nm. A plurality of Ag or WO₃ nanoparticles are homogeneously disposed on the roughened surface of the treated PC substrate.

### BACKGROUND

### Technical Field

The present disclosure is directed to a multifunctional nanocomposite, particularly to metal/metal oxide decorated polymer substrate-based multifunctional nanocomposites.

### Description of Related Art

The “background” description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present invention.

Nanostructured metal and metal oxide thin films have recently gained considerable attention due to their unique properties and wide-ranging potential applications. Attributed to their high surface area-to-volume ratio, these materials exhibit properties that show great potential across a diverse spectrum of applications such as catalysts, sensors, and energy storage devices. Nanostructured metal thin films can be fabricated through various physical and chemical methods, each endowing them with distinctive morphological, mechanical, and electrical attributes dictated by the chosen deposition technique. These properties make them ideal candidates for a myriad of applications, encompassing optical devices, magnetic data storage, and biomedical sensors. Nanostructured metal oxide thin films are promising materials for catalysis, chemical sensors, and biomedical devices. Nanostructured metal oxide thin films are applied in the detection of different hazardous gases and organic compounds. Metal oxide thin films exhibit selectivity in gas sensing, and their properties can be tailored for specific applications through engineering. Additionally, the significance of metal oxide thin films extends to energy storage devices, particularly in the realms of batteries, fuel cells, and supercapacitors. Their elevated surface area, high electronic conductivity, and excellent electrocatalytic activity constitute a few of the qualities that position them as candidates for these applications.

Metal and metal oxide thin films can be used in the realms of biomolecule sensing, environmental sample analysis, and the detection of bioanalytes such as glucose, cholesterol, and uric acid. Despite the enormous potential offered by nanostructured metal and metal oxide thin films across numerous applications, certain challenges must be addressed prior to widespread adoption. These challenges encompass aspects like large-scale synthesis and integration, toxicity, and stability concerns, among other considerations. Nanostructured metal and metal oxide thin films have given rise to new avenues in materials science, showcasing substantial promise across various applications. Developing and enhancing a fundamental understanding of their properties and processing methods will undoubtedly heighten their allure in the development of new applications that stand to make significant economic and societal contributions.

One of the emerging trends for achieving nanostructured thin films involves the utilization of nanostructured base materials decorated with functional thin films. In this context, polymers, e.g., polycarbonate (bisphenol A polycarbonate: 2,2-bis(p-hydroxyphenyl)-propane, PC), may be used as a base material [Hoekstra, Eddo J., and Catherine Simoneau. “Release of bisphenol A from polycarbonate—a review.” Critical reviews in food science and nutrition 53, no. 4 (2013): 386-402; and Fukuoka, Shinsuke, Isaburo Fukawa, Takashi Adachi, Hiroya Fujita, Naoki Sugiyama, and Toshiaki Sawa. “Industrialization and expansion of green sustainable chemical process: a review of non-phosgene polycarbonate from CO₂.” Organic Process Research & Development 23, no. 2 (2019): 145-169]. PC has attracted immense interest in many applications, mainly due to its affordability, robust durability, and high transparency. On the other hand, a generic process for transferring nanostructured features of hydrophobic PC has been developed [Yilbas, B. S., H. Ali, N. Al-Aqeeli, M. Khaled, N. Abu-Dheir, and K. K. Varanasi. “Solvent-induced crystallization of a polycarbonate surface and texture copying by polydimethylsiloxane for improved surface hydrophobicity.” Journal of Applied Polymer Science 133, no. 22 (2016)]. Hydrophobic microchannels in PC for valve-free sequential flow of multiple fluids have been reported [Jang, Minjeong, Chan Kyung Park, and Nae Yoon Lee. “Modification of polycarbonate with hydrophilic/hydrophobic coatings for the fabrication of microdevices.” Sensors and Actuators B: Chemical 193 (2014): 599-607]. However, various challenges, including controlled experimental conditions, complex treatment processes, skilled expertise, and the necessity of specialized reagents, has restricted their fabrication and implementation as multifunctional platforms.

In view of the foregoing, an objective of the present disclosure is to provide polymer-supported multifunctional metal/metal oxide substrates that can support diverse applications such as molecule detection and gas sensing. The polymer-supported multifunctional metal/metal oxide substrates include a silver (Ag) nanoparticle decorated polymer substrate, and a tungsten oxide (WO₃) nanoparticle decorated polymer substrate. A second objective of the present disclosure is to provide methods of making the polymer-supported multifunctional metal/metal oxide substrates.

### SUMMARY

In an exemplary embodiment, a silver (Ag) nanoparticle decorated polymer substrate is described. The Ag nanoparticle decorated polymer substrate includes a treated polycarbonate (PC) substrate. In some embodiments, the treated PC substrate has a roughened surface comprising polycarbonate structures in the form of circular shaped base structures covering a surface of the treated PC substrate, and nano-flowers directly grown on the circular shaped base structures. In some embodiments, the nano-flowers have elongated petals extending therefrom. In some embodiments, the circular shaped base structures have an average diameter of 2 to 10 micrometers (μm). In some embodiments, an average width of the elongated petals of the nano-flowers is in a range of 60 to 400 nanometers (nm). In some embodiments, a plurality of silver nanoparticles are homogeneously disposed on the roughened surface of the treated PC substrate. In some embodiments, an average wetting contact angle (WCA) of water on the surface of the silver-decorated polymer substrate is in a range of about 105 to 108 degrees (°).

In some embodiments, the WCA of water on a surface of the treated PC substrate is in a range of 109 to 112°.

In some embodiments, the average width of the elongated petals of the nano-flowers is in a range of 150 to 250 nm.

In some embodiments, the plurality of silver nanoparticles have an average particle size in a range of 5 to 50 nanometers (nm).

In some embodiments, the WCA of water on the surface of the silver-decorated polymer substrate is about 106.6°.

In an exemplary embodiment, a method of making the Ag nanoparticle decorated polymer substrate is described. The method includes direct current reactive sputtering silver (Ag) onto the treated PC in an inert gas to deposit Ag nanoparticles onto the surface of the treated PC substrate. In some embodiments, the Ag nanoparticles present in the Ag nanoparticle decorated polymer substrate are in the form of a discontinuous film. In some embodiments, an average thickness of the discontinuous film is about 50 nm.

In some embodiments, the direct current reactive sputtering is carried out at a power of 10 to 50 watts (W) for an appropriate amount of time, and the inert gas is introduced at a flow rate of 20 to 40 standard cubic centimeters per minute (sccm).

In some embodiments, a distance of a silver source to the treated PC substrate is in a range of 5 to 20 centimeters (cm) during the direct current reactive sputtering silver.

In some embodiments, a base pressure of the direct current reactive sputtering is maintained at 1×10⁻⁵ to 3×10⁻⁵ torr, and a working pressure of the direct current reactive sputtering is maintained at 2×10⁻³ to 4×10⁻³ torr.

In some embodiments, the method further includes preparing the treated PC substrate by immersing an untreated polycarbonate (PC) substrate in acetone for an appropriate amount of time; and removing the untreated PC substrate from the acetone, washing and drying to form the treated PC substrate. In some embodiments, the treated PC substrate has a roughened surface containing polycarbonate structures.

In some embodiments, the PC substrate is a bisphenol A polycarbonate. In some embodiments, an average wetting contact angle of water on a surface of the bisphenol A polycarbonate is in a range of 76 to 79°.

In an exemplary embodiment, a tungsten oxide (WO₃) nanoparticle-decorated polymer substrate, is described. In some embodiments, the WO₃ nanoparticle decorated polymer substrate includes a treated polycarbonate (PC) substrate. In some embodiments, the treated PC substrate has a roughened surface comprising polycarbonate structures in the form of circular-shaped base structures covering a surface of the treated PC substrate, and nano-flowers directly grown on the circular shaped base structures. In some embodiments, the nano-flowers have elongated petals extending therefrom; wherein the circular shaped base structures have an average diameter of 2 to 10 micrometers (μm). In some embodiments, an average width of the elongated petals of the nano-flowers is in a range of 60 to 400 nm. In some embodiments, a plurality of WO₃ nanoparticles disposed on the surface of the treated PC substrate. In some embodiments, an average wetting contact angle (WCA) of water on a surface of the WO₃ nanoparticle decorated polymer substrate is about 10 to 13°.

In some embodiments, the plurality of WO₃ nanoparticles have an average particle size in a range of 10 to 50 nanometers (nm).

In some embodiments. the WO₃ nanoparticle decorated polymer substrate has a cauliflower-shaped convex-concave surface, and wherein an average distance between the highest points of two adjacent convex portions on the cauliflower-shaped convex-concave surface is in a range of 300 to 900 nm.

In some embodiments, the WCA of water on the surface of the WO₃ nanoparticle decorated polymer substrate is about 11.7°.

In an exemplary embodiment, a method of making the tungsten trioxide (WO₃) nanoparticle decorated polymer substrate is described. The method includes direct current reactive sputtering tungsten (W) onto the treated PC substrate in a gaseous mixture comprising oxygen to deposit WO₃ nanoparticles onto the surface of the treated PC substrate. In some embodiments, the WO₃ nanoparticles present in the WO₃ nanoparticle decorated polymer substrate are in the form of a film. In some embodiments, an average thickness of the film is about 50 nm.

In some embodiments, the direct current reactive sputtering is carried out at a power of 10 to 50 watts (W) for an appropriate amount of time and the gaseous mixture comprising oxygen is introduced at a flow rate of 30 to 90 standard cubic centimeters per minute (sccm).

In some embodiments, the gaseous mixture further comprises an inert gas. In some embodiments, a volume ratio of the oxygen to the inert gas present in the gaseous mixture is in a range of 2:1 to 1:2.

In some embodiments, a distance of a tungsten source to the treated PC substrate is in a range of 5 to 20 centimeters (cm) during the direct current reactive sputtering tungsten.

In some embodiments, a base pressure of the direct current reactive sputtering is maintained at 1×10⁻⁵ to 3×10⁻⁵ torr, and a working pressure of the direct current reactive sputtering is maintained at 2×10⁻³ to 4×10⁻³ torr.

The foregoing general description of the illustrative present disclosure and the following The detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1 is a flowchart depicting a method of making the silver (Ag) nanoparticle decorated polymer substrate, according to certain embodiments;

FIG. 2A is a free-hand schematic for the two-step process to develop metal and metal oxide-decorated hydrophobic and hydrophilic surfaces, with insets (i), (ii), and (iii) depicting charge-coupled device (CCD) images of a pristine sample, treated sample, and a decorated treated sample, according to certain embodiments;

FIG. 2B depicts four individual sections of pristine polycarbonate (PC), treated PC, Ag-decorated pristine PC, and Ag-decorated treated PC, as mentioned therein, according to certain embodiments;

FIG. 2C depicts four individual sections of pristine polycarbonate (PC), treated PC, WO₃-decorated pristine PC, and WO₃-decorated treated PC, as mentioned therein, according to certain embodiments;

FIG. 2D depicts a scanning electron microscopic (SEM) image of the pristine PC with insets (i)-(ii) depicting Ag- and WO₃-decorated pristine PC, respectively, according to certain embodiments;

FIG. 2E depicts a SEM image of the treated PC with inset (i) depicting a high-resolution SEM image of the treated PC, according to certain embodiments;

FIG. 2F depicts a SEM image of the Ag-decorated treated PC with inset (i) depicting a high-resolution SEM image of the Ag-decorated treated PC, according to certain embodiments;

FIG. 2G depicts a SEM image of WO₃-decorated treated PC with inset (i) depicting a high-resolution SEM image of the WO₃-decorated treated PC, according to certain embodiments;

FIG. 3A shows a high-resolution field emission scanning electron microscope (FESEM) micrograph of treated PC with inset (i) showing a zoom-in view a single nano-flower showing the constituent petals, and inset (ii) showing a zoom-in view of the base nanostructure of the nano-flower, according to certain embodiments;

FIG. 3B is an inset (iii) of FIG. 3A, depicting a 3D hawk-eye view of a single nano-flower, according to certain embodiments;

FIG. 3C is an inset (iv) of FIG. 3A, depicting a line profile along the dotted line shown in inset (i), according to certain embodiments;

FIG. 3D is an inset (v) of FIG. 3A, depicting 3D hawk-eye view of base nanostructure of the nano-flower, according to certain embodiments;

FIG. 3E is an inset (vi) of FIG. 3A, depicting a line profile along the dotted line shown in inset (ii), according to certain embodiments;

FIG. 4A shows a micrograph used in SEM-aided energy dispersive X-ray spectroscopy (EDS) of treated PC with inset (i) showing EDS spectrum confirming constituent elements C and O, according to certain embodiments;

FIG. 4B is an inset (ii) of FIG. 4A, depicting an EDS mapping of the micrograph for element C, according to certain embodiments;

FIG. 4C is an inset (iii) of FIG. 4A, depicting an EDS mapping of the micrograph for element O, according to certain embodiments;

FIG. 4D is an inset (iv) of FIG. 4A, depicting an overlay mapping of micrograph and those of element C and O, according to certain embodiments;

FIG. 5A shows a high-resolution FESEM micrograph of Ag-decorated treated PC with inset (i) showing a zoom-in view a single nano-flower decorated with Ag, and inset (ii) showing a zoom-in view of the base nanostructure decorated with Ag, according to certain embodiments;

FIG. 5B is an inset (iii) of FIG. 5A, depicting a 3D hawk-eye view of an Ag-decorated single nano-flower showing constituent petals decorated with Ag, according to certain embodiments;

FIG. 5C is an inset (iv) of FIG. 5A, depicting a line profile along the dotted line shown in inset (i), according to certain embodiments;

FIG. 5D is an inset (v) of FIG. 5A, depicting a 3D hawk-eye view of base nanostructure confirming Ag decoration, according to certain embodiments;

FIG. 5E is an inset (vi) of FIG. 5A, depicting a line profile along the dotted line shown in inset (ii), according to certain embodiments;

FIG. 6A shows a micrograph used in SEM-aided EDS of Ag-decorated treated PC, according to certain embodiments;

FIG. 6B is an inset (i) of FIG. 6A, depicting an EDS spectra of entire square and a dot confirming constituent elements Ag, C, and O at a position of spectrum 4, according to certain embodiments;

FIG. 6C is an inset (ii) of FIG. 6A, depicting an EDS spectra of entire square and a dot confirming constituent elements Ag, C, and O at a position of spectrum 5, according to certain embodiments;

FIG. 6D is an inset (iii) of FIG. 6A, depicting an EDS mapping of the micrograph for element C, according to certain embodiments;

FIG. 6E is an inset (iv) of FIG. 6A, depicting an EDS mapping of the micrograph for element Ag, according to certain embodiments;

FIG. 6F is an inset (v) of FIG. 6A, depicting an EDS mapping of the micrograph for element O, according to certain embodiments;

FIG. 6G is an inset (vi) of FIG. 6A, showing an overlay mapping of micrograph and those of element Ag, C, and O, according to certain embodiments;

FIG. 7A shows a high-resolution FESEM micrograph of WO₃-decorated treated PC, with inset (i) showing a zoom-in view of the base nanostructure decorated with WO₃, and inset (ii) showing a zoom-in view a single nano-flower decorated with WO₃, according to certain embodiments;

FIG. 7B is an inset (iii) of FIG. 7A, depicting a 3D hawk-eye view of base nanostructure confirming WO₃ decoration, according to certain embodiments;

FIG. 7C is an inset (iv) of FIG. 7A, depicting a line profile along the dotted line shown in inset (i), according to certain embodiments;

FIG. 7D is an inset (v) of FIG. 7A, depicting a 3D hawk-eye view of a WO₃-decorated single nano-flower showing constituent petals totally covered with WO₃, according to certain embodiments;

FIG. 7E is an inset (vi) of FIG. 7A, depicting a line profile along the dotted line shown in inset (ii), according to certain embodiments;

FIG. 8A is a micrograph used in SEM-aided EDS of WO₃-decorated treated PC, according to certain embodiments;

FIG. 8B is an inset (i) of FIG. 8A, depicting an EDS spectra of an entire square and a dot confirming constituent elements C, O, and W respectively at a position of spectrum 9, according to certain embodiments;

FIG. 8C is an inset (ii) of FIG. 8A, depicting an EDS spectra of an entire square and a dot confirming constituent elements C, O, and W respectively at a position of spectrum 10, according to certain embodiments;

FIG. 8D is an inset (iii) of FIG. 8A, depicting an EDS mapping of the micrograph for element C, according to certain embodiments;

FIG. 8E is an inset (iv) of FIG. 8A, depicting an EDS mapping of the micrograph for element O, according to certain embodiments;

FIG. 8F is an inset (v) of FIG. 8A, depicting an EDS mapping of the micrograph for element W, according to certain embodiments;

FIG. 8G is an inset (vi) of FIG. 8A, depicting an overlay mapping of micrograph and those of constituent elemental mappings, according to certain embodiments;

FIG. 9A is a CCD image of a droplet on an Ag-sputtered glass substrate confirming water contact angle (WCA), with the inset showing the same on glass substrate, according to certain embodiments;

FIG. 9B shows a CCD image of a droplet on the Ag-decorated pristine PC, with the inset showing the same on pristine PC, according to certain embodiments;

FIG. 9C shows a CCD image of a droplet on the Ag-decorated treated PC, with the inset showing the same on treated PC, according to certain embodiments;

FIG. 9D shows a CCD image of a droplet on the WO₃-decorated PC, according to certain embodiments;

FIG. 9E shows a CCD image of a droplet on the WO₃-decorated treated PC, according to certain embodiments; and

FIG. 9F is a bar diagram showing average WCA obtained on various substrates, namely-glass, pristine PC, treated PC, Ag-glass, Ag-decorated PC, Ag-decorated treated PC, WO₃-decorated PC, WO₃-decorated treated PC, according to certain embodiments.

### DETAILED DESCRIPTION

In the drawings, reference numerals designate identical or corresponding parts throughout the several views. Further, as used herein, the words “a,” “an,” and the like generally carry a meaning of “one or more,” unless stated otherwise.

As used herein, “particle size” and “pore size” may be thought of as the lengths or longest dimensions of a particle and of a pore opening, respectively.

The present disclosure is intended to include all hydration states of a given compound or formula, unless otherwise noted or when heating a material.

As used herein, the terms “about,” “approximately,” or “substantially similar” may be used when describing magnitude and/or position to indicate that the value and/or position described is within a reasonable range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), +/−15% of the stated value (or range of values), or +/−20% of the stated value (or range of values). Within the description of this disclosure, where a numerical limit or range is stated, the endpoints are included unless stated otherwise. Also, all values and subranges within a numerical limit or range are specifically included as if explicitly written out.

Aspects of the present disclosure are directed to the development of polymer-supported multifunctional surfaces. In one aspect a two-step process is disclosed. In the first step, commercially available polycarbonate (PC) was treated to modify the hydrophobicity of the active surface to obtain an average wetting contact angle (WCA) as high as preferably about 110.5°. The second step involved the decoration of such a hydrophobic surface with metal (Ag nanoparticles) and metal oxide (WO₃), facilitating the achievement of a hydrophobic and hydrophilic surface, respectively. The polymer-supported multifunctional metal/metal oxide surfaces can support diverse applications such as molecule detection and gas sensing.

A metal or metal oxide nanoparticle-decorated polymer substrate is described. In an embodiment, the metal is at least one selected from the group consisting of gold, silver (Ag), platinum, palladium, copper, rhodium, ruthenium, nickel, cobalt, iron, titanium, zinc, aluminum, iridium, and tin. In a preferred embodiment, the metal is Ag. In an embodiment, the metal oxide is at least one selected from the group consisting of tungsten oxide (WO₃), titanium dioxide, iron oxide, zinc oxide, aluminum oxide, cerium oxide, silicon dioxide, copper oxide, tin oxide, manganese oxide, nickel oxide, cobalt oxide, and chromium oxide. In a preferred embodiment, the metal oxide in the metal oxide nanoparticle-decorated polymer substrate is WO₃. The WO₃ disclosed in the present disclosure may exist in various phases, such as alpha, beta, gamma, delta, epsilon, or in combinations thereof. For example, in an embodiment, WO₃ exists in the epsilon phase. In some embodiments, the WO₃ exists in the gamma phase. In some embodiments, the WO₃ can be prepared by various methods known to those of skill in the art—for example, thermal plasma (direct current and including radio frequency inductively-coupled plasma (RF-ICP)), solvothermal, solid-state reaction, pyrolysis (spray and flame), and combustion.

In some embodiments, the metal nanoparticle-decorated polymer substrate is a silver (Ag) nanoparticle-decorated polymer substrate. In an embodiment, the metal oxide nanoparticle-decorated polymer substrate is a tungsten oxide (WO₃) nanoparticle-decorated polymer substrate. In some embodiments, the metal or metal oxide nanoparticle-decorated polymer substrate includes at least one polymer selected from the group consisting of polyethylene, polypropylene, polyethylene terephthalate, polystyrene, polyvinyl chloride, polyvinyl alcohol, polyurethane, polydimethylsiloxane, polycarbonate, poly(methyl methacrylate), polyethylene oxide, poly(lactic acid), polyhydroxyalkanoate, and polyimide. In some preferred embodiments, the polymer substrate is a treated polycarbonate substrate.

As used herein, polycarbonates (PC) are a group of thermoplastic polymers containing carbonate groups (—O—(C═O)—O—) in their chemical structures. Polycarbonates are substantially transparent polymers comprising monomers containing hydrophobic phenyl and methyl groups and a hydrophilic carbonate group. As used herein, a thermoplastic or thermosoftening plastic is a plastic material, a polymer that becomes pliable or moldable above a specific temperature and solidifies upon cooling. Many polymer thermoplastics are considered glass or polymer glass (i.e., acrylic glass, polycarbonate, and polyethylene terephthalate) and are a lighter alternative to traditional glass. It is equally envisioned that the glass comprising a polycarbonate may comprise one or more additional thermoplastics. These thermoplastics may be used in addition to or in lieu of a polycarbonate. Exemplary additional thermoplastics include, but are not limited to, acrylic, poly (methyl methacrylate (PMMA), acrylonitrile butadiene styrene (ABS), nylon, polylactic acid (polylactide), polybenzimidazole, polyether sulfone, polyether ether ketone (PEEK), polyetherimide (PEI), polyethylene (PE, UHMWPE, HDPE, MDPE, LDPE, XLPE, PEX), polyphenylene oxide (PPO), polyphenylene sulfide (PPS), polypropylene (PP), polystyrene, polyvinyl chloride, Teflon, and the like.

In a preferred embodiment, the polycarbonate is produced from the precursor monomer bisphenol A. The majority of polycarbonate materials are produced by the reaction of bisphenol A (BPA) with phosgene COCl₂. As used herein, bisphenol A refers to an organic synthetic compound with the chemical formula (CH₃)₂C(C₆H₄OH)₂ belonging to the group of diphenylmethane derivatives and bisphenols, with two hydroxyphenyl groups. It is equally envisioned that one or more additional precursor monomers may produce the polycarbonate. Exemplary additional precursor monomers that may be used in addition to, or in lieu of bisphenol A, include, but are not limited to, bisphenol AP, bisphenol AF, bisphenol B, bisphenol BP, bisphenol C, bisphenol C 2, bisphenol E, bisphenol F, bisphenol G, bisphenol M, bisphenol S, bisphenol P, bisphenol PH, bisphenol TMC, bisphenol Z, MBHA, BisOPP-A, PHBB, 2,4-BPS, TGSA, BPS-MAE, BPS-MPE, 4-hydroxyphenyl, and the like.

In some embodiments, the treated PC substrate is obtained by immersing a commercially procured PC substrate in a polar aprotic solvent for a sufficient period to obtain the treated PC substrate. Suitable examples of polar aprotic solvents include, acetone (2-propanone), dichloromethane, chloroform, tetrahydrofuran, dimethyl sulfoxide, diethyl ether, or a mixture thereof. In a preferred embodiment, the polar aprotic solvent is acetone.

One of the important parameters that affect the material's properties is the immersion duration. In an embodiment, the commercially procured PC substrate is immersed in the polar aprotic solvent, preferably acetone, for a period of 5-15 minutes, preferably 6-14 minutes, preferably 7-13 minutes, preferably 7-10 minutes, preferably 7-9 minutes, preferably 7 minutes to obtain the treated PC substrate. In some embodiments, the immersion is carried out at a temperature range of 20-35° C., preferably 25-30° C./room temperature, to obtain the treated substrate. Other ranges are also possible.

The wetting properties of the treated PC substrate were examined. One measure for surface hydrophilicity/hydrophobicity is the droplet contact angle of a liquid; common and exemplary liquids include, but are not limited to, water, glycerol, and diiodomethane. As used herein, the term “hydrophobic” surface generally refers to surfaces that have a contact angle from 90-150° with a droplet of water, and the term “hydrophilic” surface generally refers to surfaces that have a contact angle between 0-90° with a droplet of water.

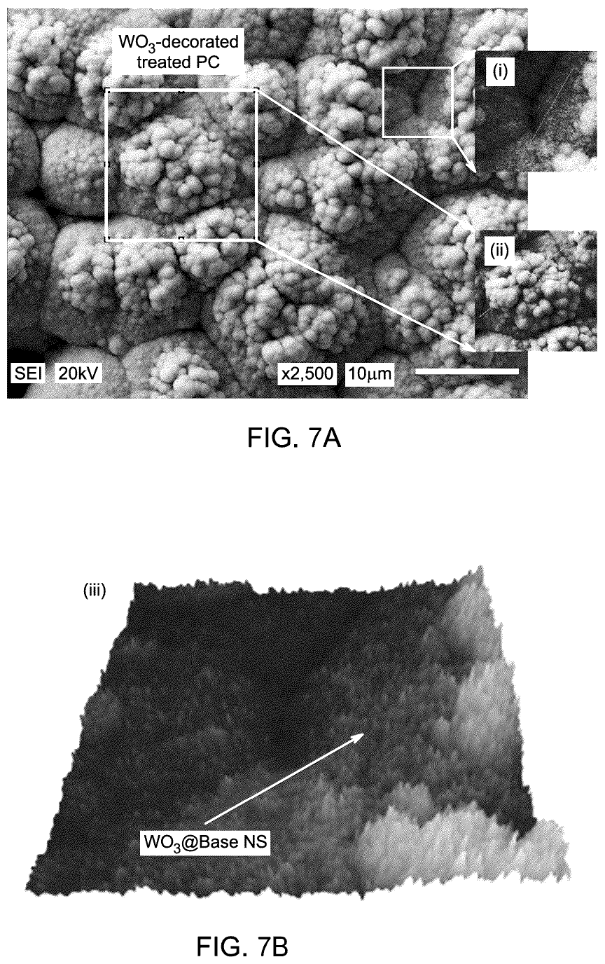

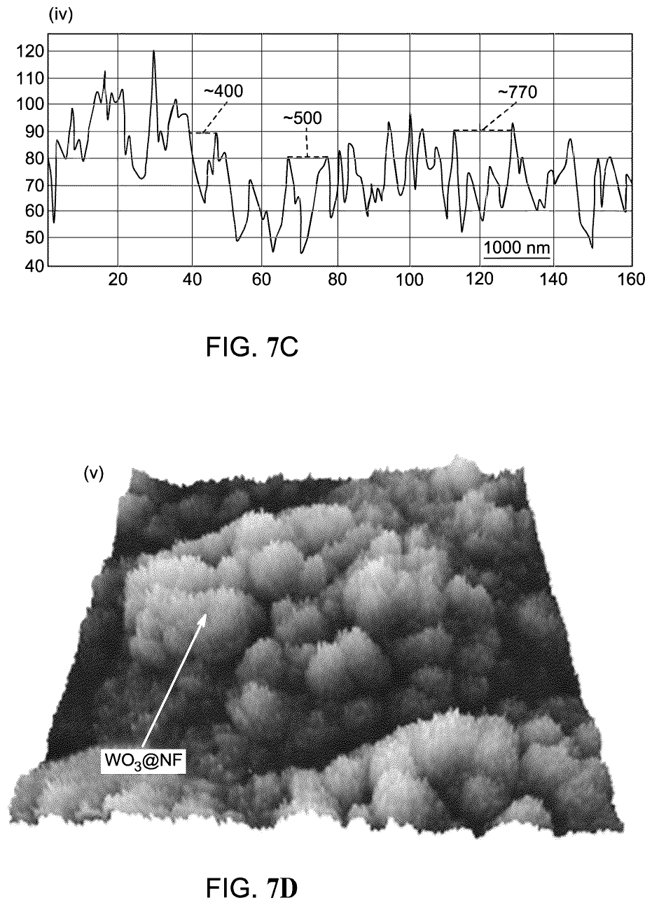

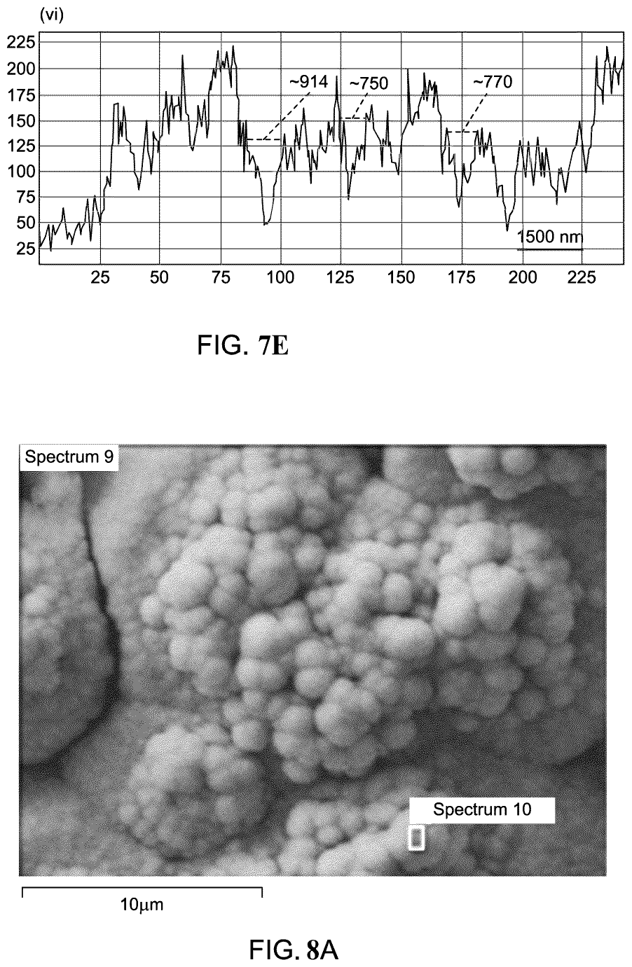

Referring to FIGS. 7A to 9F, the water contact angle was obtained by the sessile drop method on surfaces of glass, pristine PC, treated PC, Ag-glass, Ag-decorated PC, Ag-decorated treated PC, WO₃-decorated PC, WO₃-decorated treated PC, respectively by using a contact angle goniometer instrument, e.g., DSA25, Denmark. The water contact angle WCA was taken on at least two, preferably at least four different positions on the material tested and the average value was recorded. The thickness of the membranes was recorded by taking measurements from at least 5, preferably at least 10 different spots on the corresponding substrate to generate corresponding data using LITEMATIC VL-50A, manufactured by Mitutoyo measuring instrument.

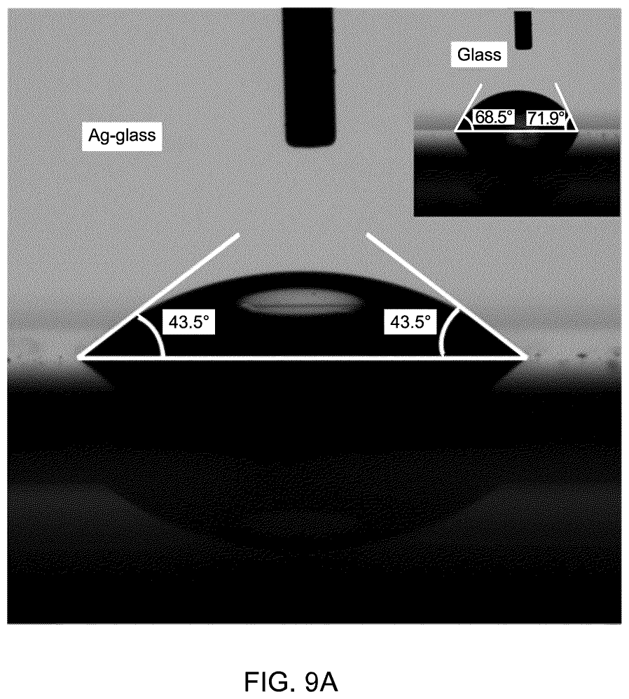

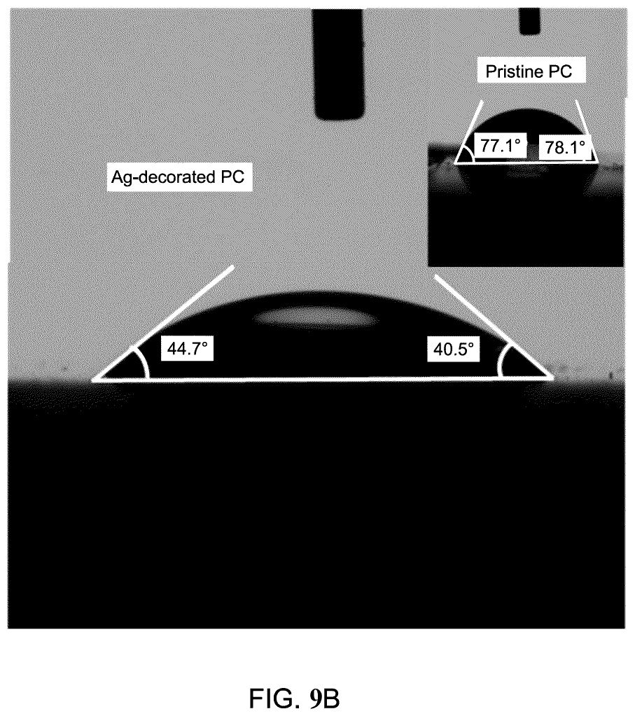

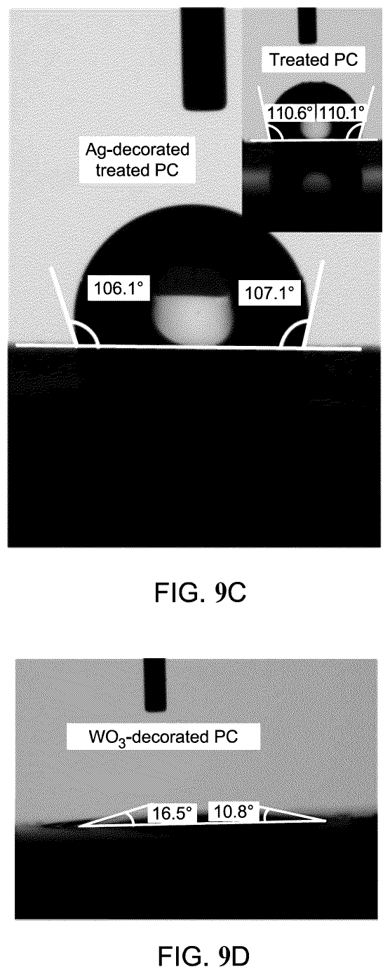

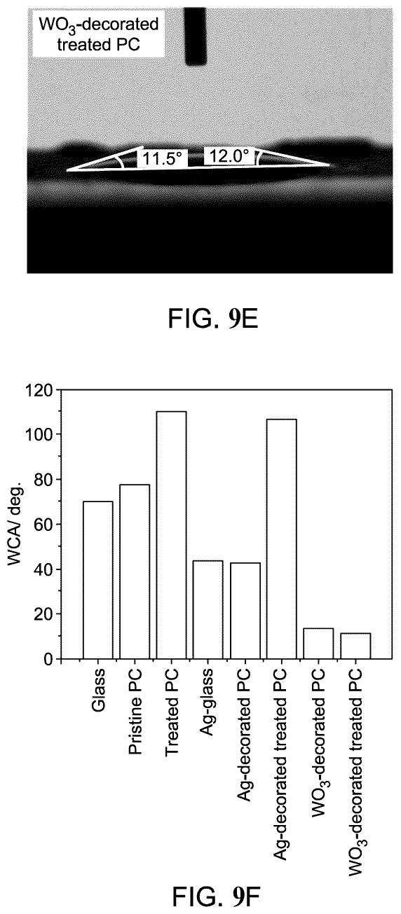

In some embodiments, the water contact angle (WCA) of water on a surface of the glass substrate is in a range of 65 to 75°, preferably 68 to 73°, or even more preferably about 71°, as depicted in FIG. 9A. In some embodiments, the WCA of water on a surface of the silver decorated glass substrate is in a range of 40 to 47°, preferably 42 to 45°, or even more preferably about 43°, as depicted in FIG. 9A. Other ranges are also possible.

In some embodiments, the water contact angle (WCA) of water on a surface of the pristine PC substrate is in a range of 72 to 83°, preferably 74 to 71°, or even more preferably about 75 to 79°, as depicted in FIG. 9B. In some embodiments, the WCA of water on a surface of the silver decorated pristine PC substrate is in a range of 35 to 50°, preferably 40 to 45°, or even more preferably about 43°, as depicted in FIG. 9B. Other ranges are also possible.

In some embodiments, the water contact angle (WCA) of water on a surface of the treated PC substrate is in a range of 105 to 115°, preferably 108 to 112°, or even more preferably about 110 to 111°, as depicted in FIG. 9C. In some embodiments, the WCA of water on a surface of the Ag-decorated treated PC substrate is in a range of 100 to 110°, preferably 103 to 107°, or even more preferably about 106°, as depicted in FIG. 9C. Other ranges are also possible.

In some embodiments, the water contact angle (WCA) of water on a surface of the WO₃-decorated PC substrate is in a range of 5 to 20°, preferably 8 to 17°, or even more preferably about 11 to 16°, as depicted in FIG. 9D. In some embodiments, the WCA of water on a surface of the WO₃-decorated treated PC substrate is in a range of 3 to 18°, preferably 8 to 16°, or even more preferably about 10 to 14°, as depicted in FIG. 9E. Other ranges are also possible.

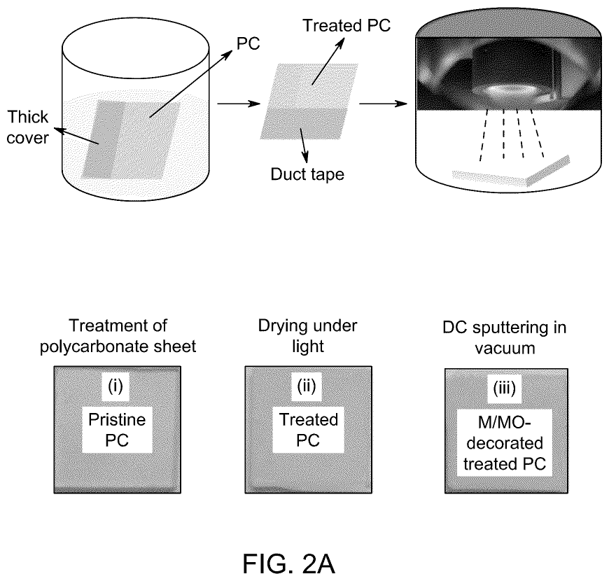

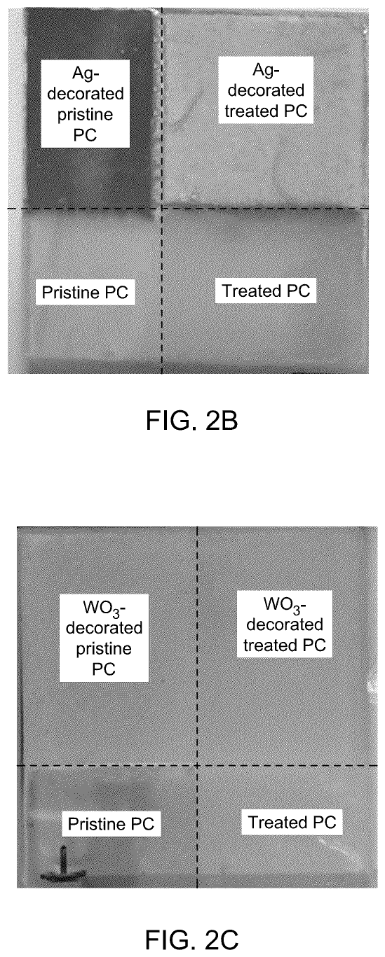

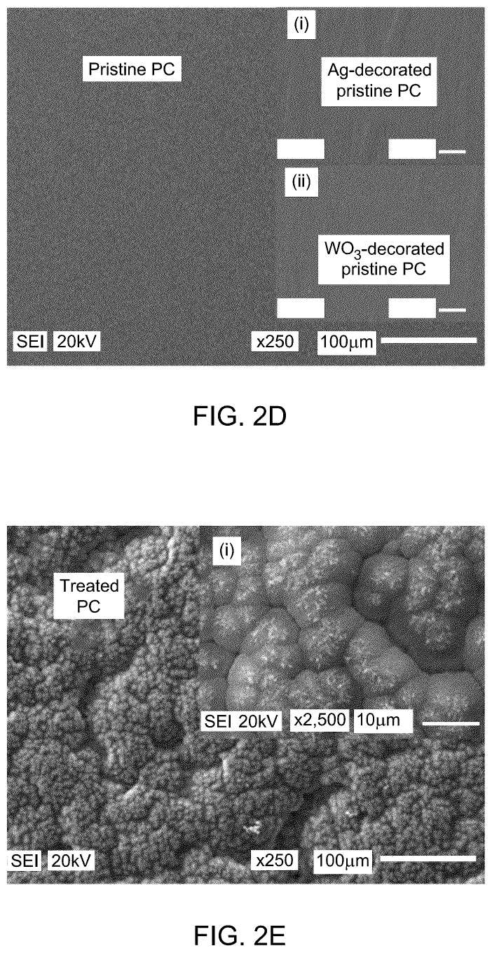

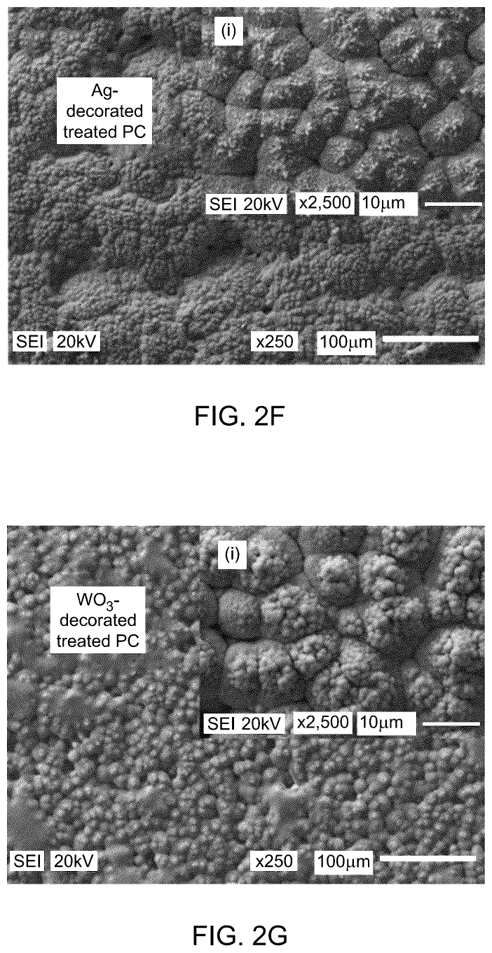

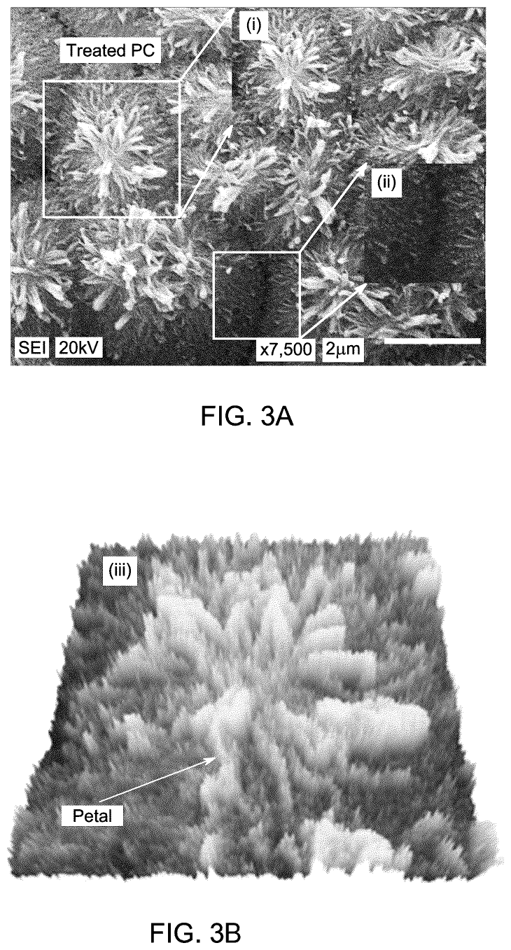

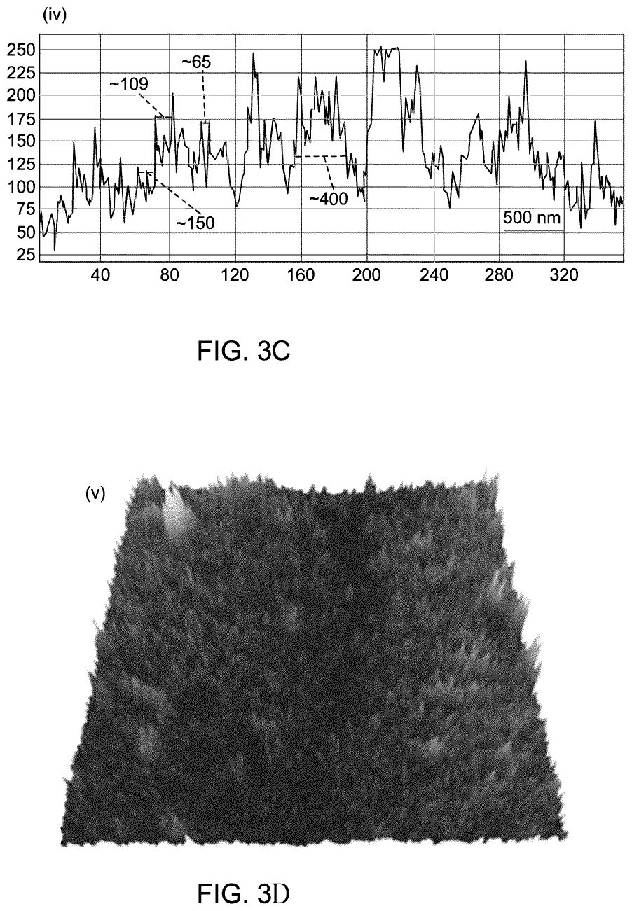

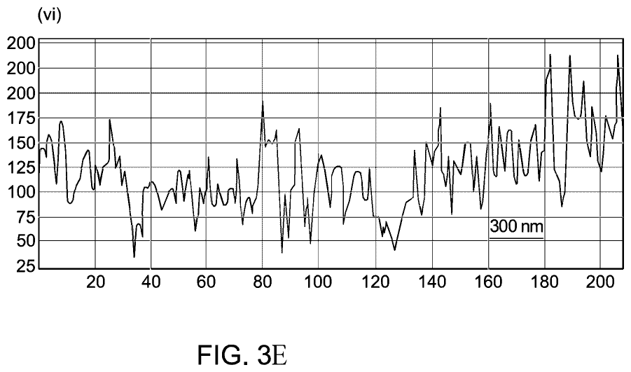

In some embodiments, the treated PC substrate has a roughened surface and includes polycarbonate structures in the form of circular-shaped base structures covering the surface of the treated PC substrate, as depicted in FIGS. 2E, and 3A. The circular-shaped base structures have an average diameter of 0.5 to 20 micrometers (μm), preferably 1 to 15 μm, preferably 3 to 10 μm, or even more preferably 5 to 8 μm, as depicted in FIGS. 3B to 3E. Other ranges are also possible. The treated PC substrate further includes nano-flowers that directly grown on the circular-shaped base structures. The nano-flowers have elongated petals extending therefrom. The average width of the elongated petals of the nano-flowers is in a range of 60 to 400 nm. In some embodiments, the average width of the elongated petals of the nano-flowers is preferably in a range of 80 to 350 nm, preferably 90-300 nm, preferably 100-290 nm, preferably 100-280 nm, preferably 110-270 nm, preferably 120-260 nm, preferably 130-250 nm, preferably 150-250 nm, as depicted in FIGS. 3B to 3E. Other ranges are also possible.

As used herein, the term “rough surface,” “roughened surface,” or “rough surface morphology” generally refers to the physical characteristics or features of a surface that deviate from smoothness or regularity. The term “roughened surface” may include unevenness, irregularities, and variations in height, shape, or texture of a surface at a micro or macro scale. In the present disclosure, the rough surface morphology of the treated PC substrate includes, but is not limited to, bumps, ridges, hills, valleys, peaks, or irregular shapes that may be randomly distributed or organized in a specific pattern. Additionally, the surface roughness may be determined by roughness average (Ra), root mean square (RMS) roughness, or peak-to-valley height. Roughness average (Ra) is calculated by averaging the surface roughness of at least 5, and preferably at least 10, representative locations spaced approximately evenly across the portion of the article carrying the treated PC substrate. In some embodiments, it is preferred to measure the thickness at representative points across the longest dimension of the portion of the article that is covered with the treated PC substrate. The standard deviation of roughness is found by calculating the standard deviation of the local average roughness across at least 5, and preferably at least 10, representative locations spaced approximately evenly across the portion of the article carrying the treated PC substrate. Arithmetic average roughness (Sa) is the areal (3D) equivalent of two-dimensional Ra. Sa generally refers to the average height of all measured points in the areal measurement.

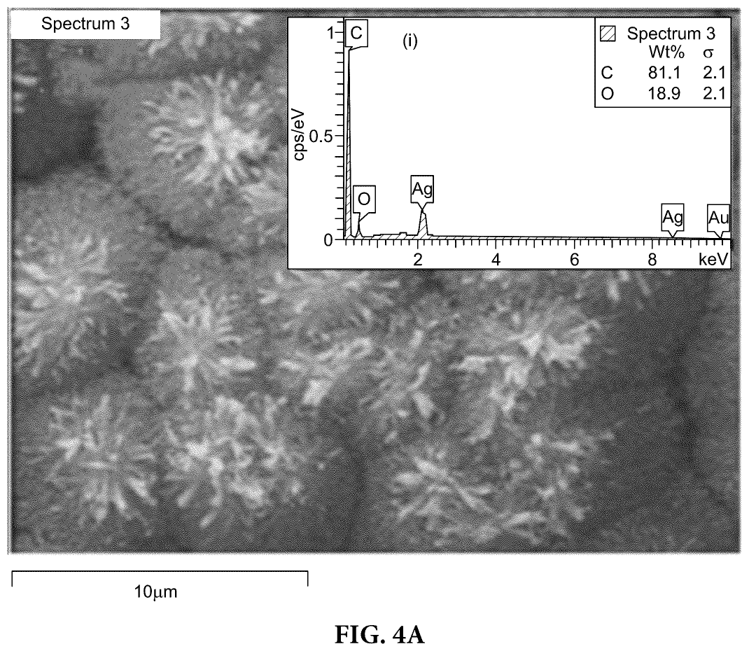

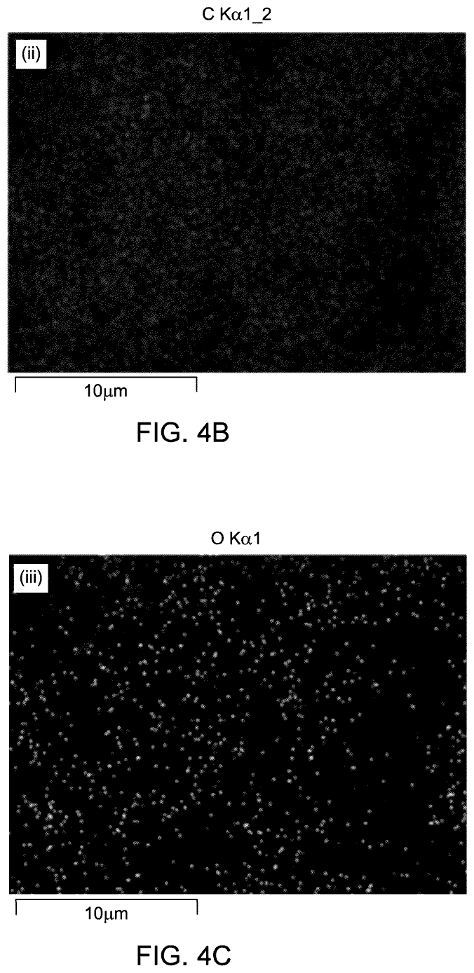

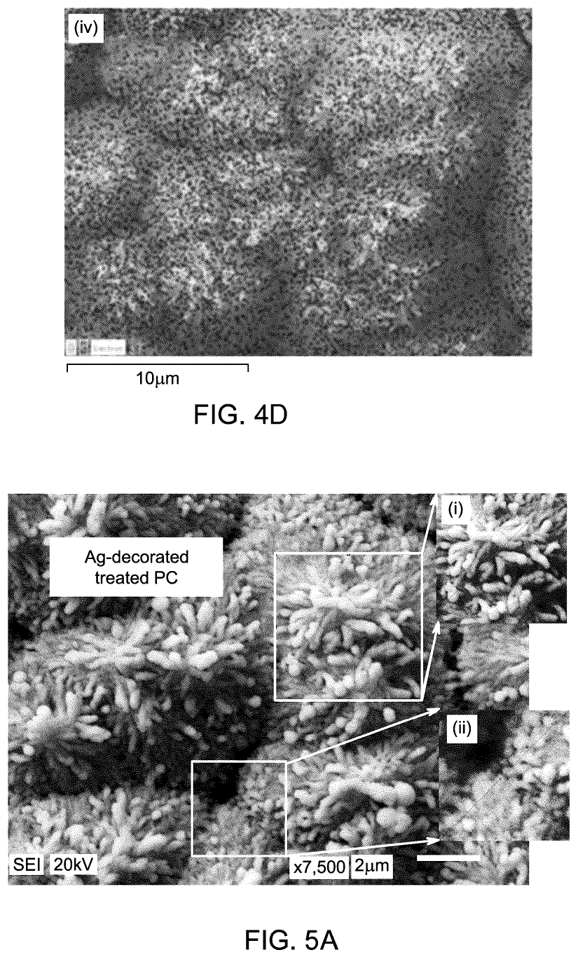

Elemental analysis of the treated PC substrate shows the presence of carbon in a weight percentage range of 60-90 wt. %, preferably 65-87 wt. %, preferably 70-85 wt. %, preferably 75-84 wt. %, preferably 76-83 wt. %, preferably 77-82 wt. %, preferably 80-82 wt. %, preferably 81.89 wt. %; and oxygen in a weight percentage range of 10-40 wt. %, preferably 12-35 wt. %, preferably 15-30 wt. %, preferably 17-25 wt. %, preferably 18-20 wt. %, preferably 18.9 wt. %, each wt. % based on a total weight of the treated PC substrate, as depicted in FIGS. 4A to 4D. Other ranges are also possible.

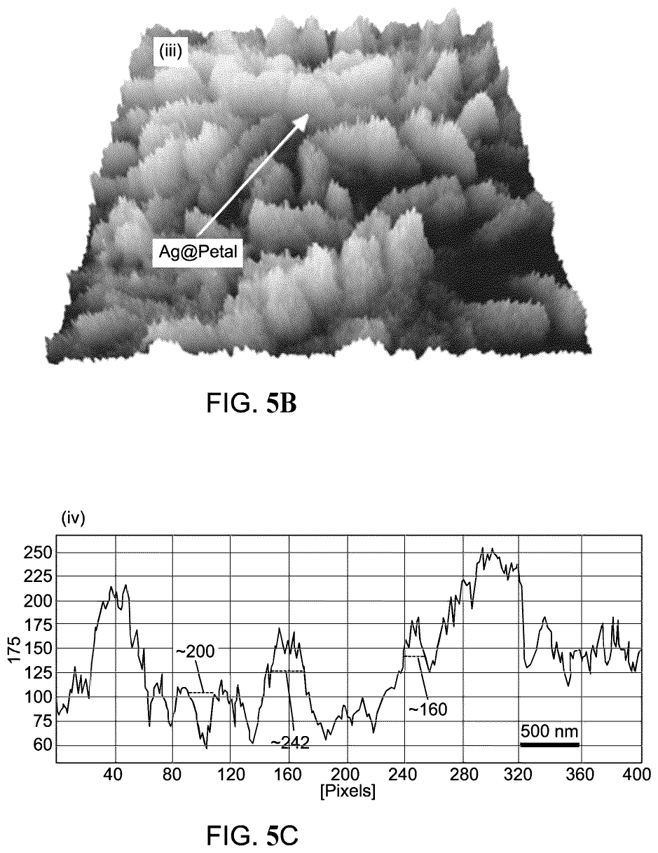

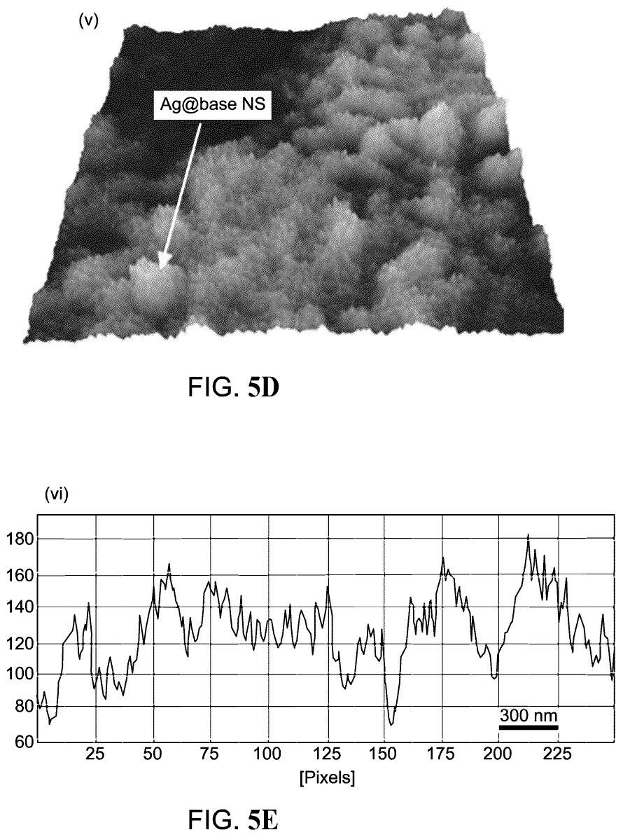

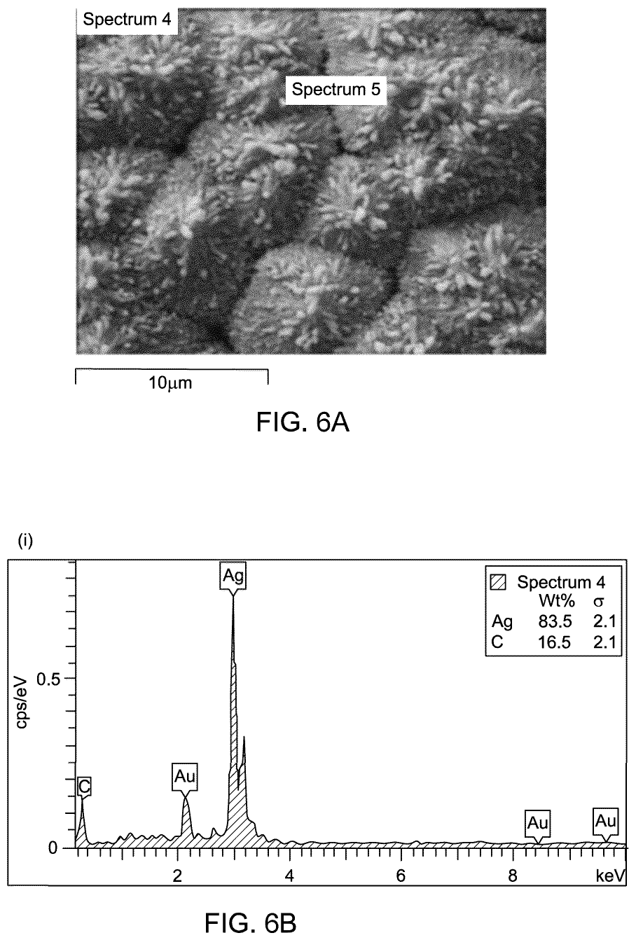

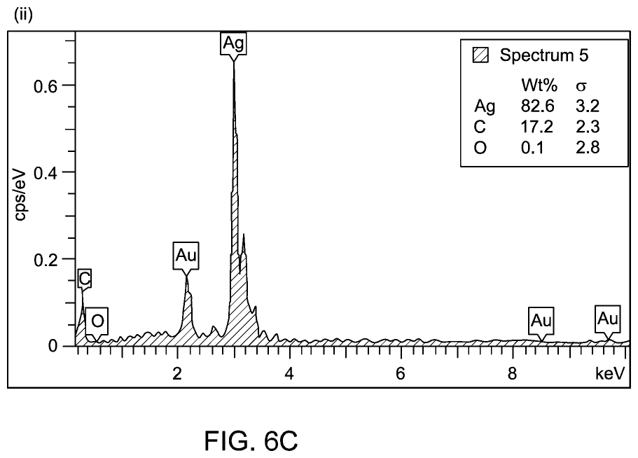

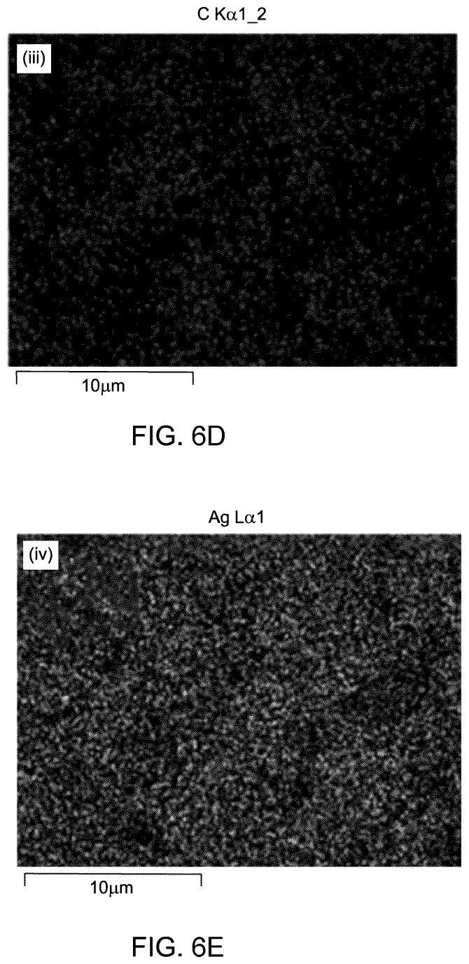

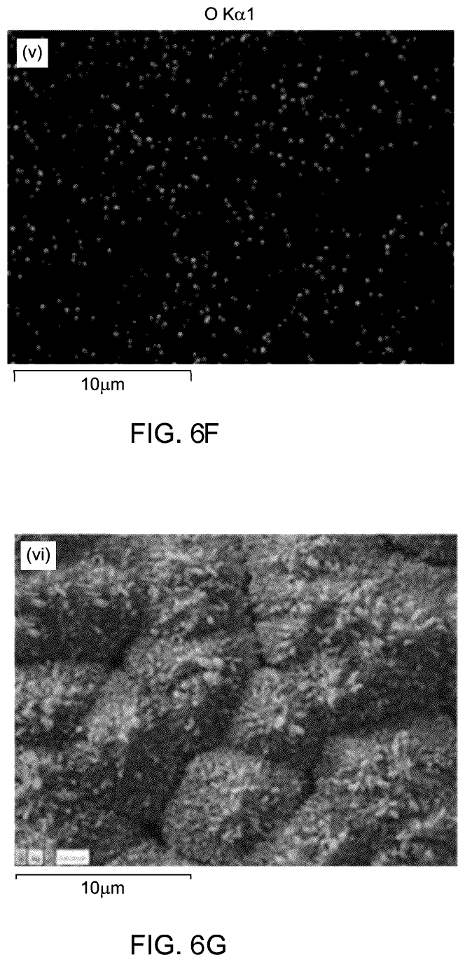

The Ag nanoparticle-decorated polymer substrate further includes a plurality of silver nanoparticles homogeneously disposed on the roughened surface of the treated PC substrate. In an embodiment, the silver nanoparticles have an average particle size in a range of 5 to 50 nanometers (nm), preferably 10 to 45 nm, preferably 15 to 40 nm, preferably 20 to 35 nm, or even more preferably 25 to 30 nm, as depicted in FIGS. 5A and 5B. Other ranges are also possible. Elemental analysis of the Ag nanoparticle-decorated polymer substrate shows the presence of Ag in a weight percentage ranging from 60-90 wt. %, preferably 65-87 wt. %, preferably 70-85 wt. %, preferably 75-85 wt. %, preferably 76-85 wt. %, preferably 77-85 wt. %, preferably 80-85 wt. %; and carbon in a weight percentage ranging from 10-40 wt. %, preferably 12-35 wt. %, preferably 15-30 wt. %, preferably 15-25 wt. %, preferably 15-20 wt. %; and oxygen in an amount ranging from 0-5 wt. %, preferably 0-4 wt. %, preferably 0-3 wt. %, preferably 0-1 wt. %, preferably 0-0.5 wt. %, each wt. % based on a total weight of the Ag nanoparticle-decorated polymer substrate, as depicted in FIGS. 6A to 6G.

The WO₃ nanoparticle-decorated polymer substrate further includes a plurality of WO₃ nanoparticles disposed on the surface of the treated PC substrate. In an embodiment, the WO₃ nanoparticles have an average particle size in a range of 10 to 50 nanometers (nm), preferably 15 to 45 nm, preferably 20 to 40 nm, preferably 25 to 35 nm, or even more preferably about 30 nm, as depicted in FIGS. 7A and 7B. Other ranges are also possible. In some embodiments, the WO₃ nanoparticle decorated polymer substrate has a cauliflower-shaped convex-concave surface. An average distance between the highest points of two adjacent convex portions on the cauliflower-shaped convex-concave surface is in a range of 300 to 900 nm, preferably 400 to 800 nm, preferably 500 to 700 nm, or even more preferably about 600 nm, as depicted in FIGS. 7C to 7E. Other ranges are also possible.

As used herein, “nanoparticles” are particles (particles of silver or WO₃) having a particle size of 1 nm to 500 nm within the scope of the present invention. The nanoparticles may exist in various morphological shapes, such as nanowires, nanocrystals, nanorectangles, nanotriangles, nanopentagons, nanohexagons, nanoprisms, nanodisks, nanocubes, nanoribbons, nanoblocks, nanobeads, nanotoroids, nanodiscs, nanobarrels, nanogranules, nanowhiskers, nanoflakes, nanofoils, nanopowders, nanoboxes, nanostars, tetrapods, nanobelts, nano-urchins, nanofloweres, etc., and mixtures thereof.

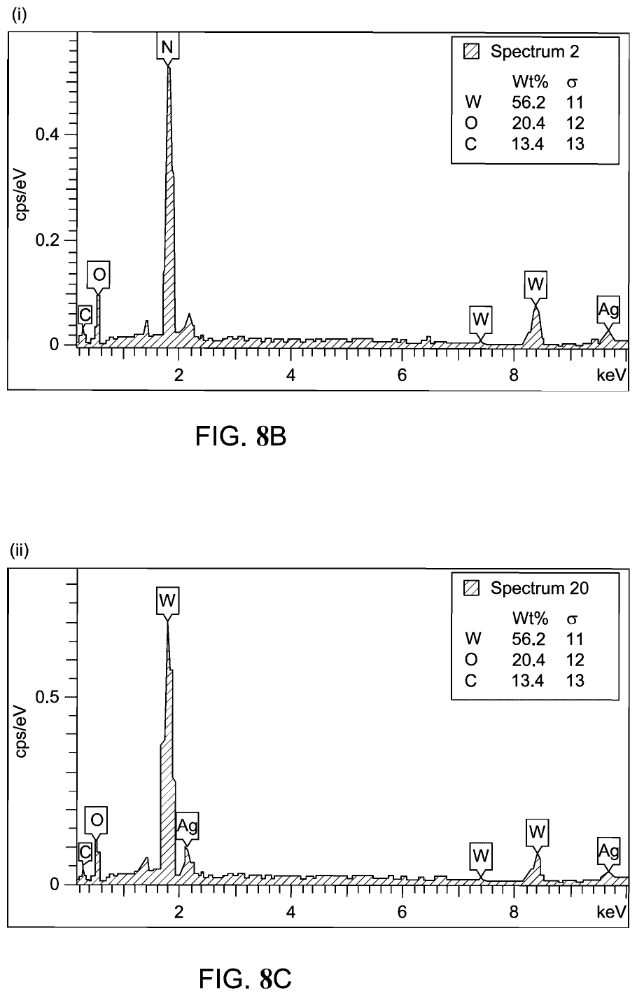

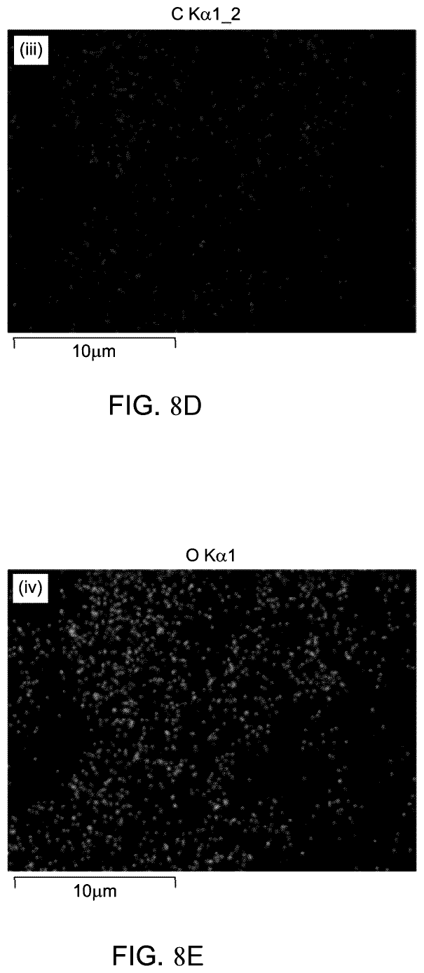

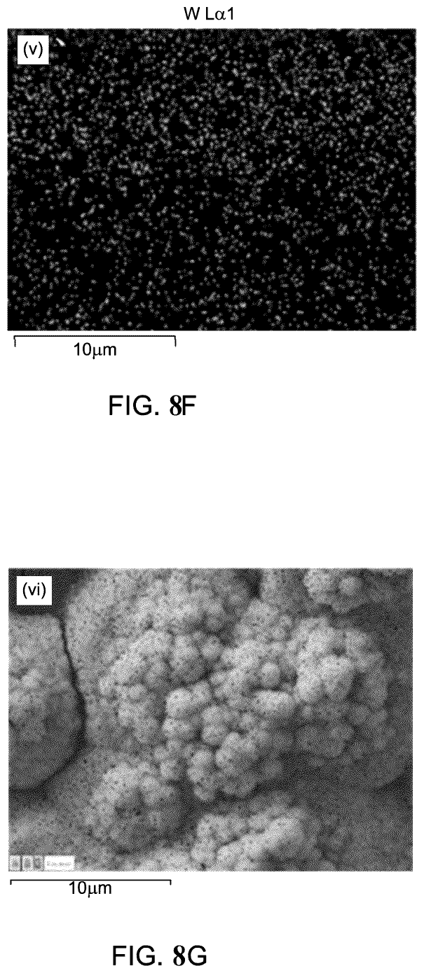

Elemental analysis of the WO₃-nanoparticle-decorated polymer substrate shows the presence of W in a weight percentage ranging from 50-90 wt. %, preferably 55-80 wt. %, preferably 60-75 wt. %, preferably 60-70 wt. %, and oxygen in a weight percentage ranging from 10-40 wt. %, preferably 15-35 wt. %, preferably 18-30 wt. %, preferably 20-30 wt. %; and carbon in a weight percentage ranging from 10-20 wt. %, or even more preferably about 15 wt. %, each wt. % based on a total weight of the WO₃-nanoparticle-decorated polymer substrate, as depicted in FIGS. 8A to 8G. Other ranges are also possible.

The wetting properties of the Ag nanoparticle-decorated polymer substrate and the WO₃ nanoparticle-decorated polymer substrate were examined. The average wetting contact angle (WCA) of water on the surface of the silver-decorated polymer substrate is in a range of about 105 to 108 degrees (°), preferably 106-107°, preferably 106.6° indicating its hydrophobic nature, while the average wetting contact angle (WCA) of water on the surface of the WO₃ nanoparticle decorated polymer substrate is about 10 to 13°, preferably 11-12°, and more preferably 11.7° indicating its hydrophilic nature. Other ranges are also possible.

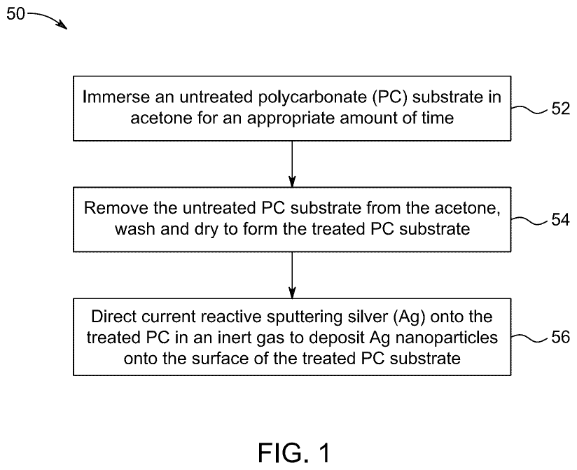

FIG. 1 illustrates a flow chart of a method 50 of preparing the silver (Ag) nanoparticle decorated polymer substrate. The order in which the method 50 is described is not intended to be construed as a limitation, and any number of the described method steps can be combined in any order to implement the method 50. Additionally, individual steps may be removed or skipped from the method 50 without departing from the spirit and scope of the present disclosure.

At step 52, the method 50 includes immersing an untreated polycarbonate (PC) substrate in acetone for an appropriate amount of time. Examples of PC substrates include bisphenol A, bisphenol AP, bisphenol AF, bisphenol B, bisphenol BP, bisphenol C, bisphenol C 2, bisphenol E, bisphenol F, bisphenol G, bisphenol M, bisphenol S, bisphenol P, bisphenol PH, bisphenol TMC, bisphenol Z, MBHA, BisOPP-A, PHBB, 2,4-BPS, TGSA, BPS-MAE, BPS-MPE, 4-hydroxyphenyl, and the like. In a preferred embodiment, the PC substrate is a bisphenol A polycarbonate. The average wetting contact angle of water on the surface of the bisphenol A polycarbonate is in a range of 76 to 79°. The untreated PC substrate is immersed in acetone or any other polar aprotic solvent for a sufficient period to obtain the PC substrate. Suitable examples of polar aprotic solvents include, acetone (2-propanone), dichloromethane, chloroform, tetrahydrofuran, dimethyl sulfoxide, diethyl ether, or a mixture thereof. In a preferred embodiment, the polar aprotic solvent is acetone. One of the parameters that affect the material's properties is the immersion duration. In an embodiment, the commercially procured PC substrate is immersed in the polar aprotic solvent, preferably acetone, for a period of 5-15 minutes, preferably 6-14 minutes, preferably 7-13 minutes, preferably 7-10 minutes, preferably 7-9 minutes, preferably 7 minutes to obtain the treated PC substrate. In some embodiments, the immersion is carried out at a temperature range of 20-35° C., preferably 25-30° C./room temperature. Other ranges are also possible.

At step 54, the method 50 includes removing the untreated PC substrate from the acetone, washing, and drying to form the treated PC substrate. The untreated PC substrate is then removed from the polar aprotic solvent/acetone and is further washed to remove any impurities. The washed PC substrate is further dried to evaporate the solvent, forming the treated PC substrate. The treated PC substrate has a roughened surface containing polycarbonate structures.

At step 56, the method 50 includes direct current reactive sputtering silver (Ag) onto the treated PC in an inert gas to deposit Ag nanoparticles onto the surface of the treated PC substrate. In some embodiments, the direct current reactive sputtering is carried out at a power of 10 to 50 watts (W), preferably 15-45 W, preferably 20-40 W, preferably 25-35 W, and preferably 30 W for an appropriate amount of time. Other ranges are also possible. In some embodiments, the inert gas is introduced at a flow rate of 20 to 40 standard cubic centimeters per minute (sccm), preferably 25-35 sccm, preferably 28-32 sccm, preferably 30 sccm. Other ranges are also possible. In some embodiments, the inert gas is preferably Argon. Optionally, other inert gases, such as Helium, may be used as well. In some embodiments, other gases such as oxygen/nitrogen/a combination thereof may be used in combination with the inert gas. In some embodiments, a distance of a silver source to the treated PC substrate is in a range of 5 to 20 centimeters (cm), preferably 7-17 cm, preferably 8-15 cm, preferably 9-12 cm, preferably 10-12 cm, preferably 10 cm, during the direct current reactive sputtering silver. Other ranges are also possible. In some embodiments, a base pressure of the direct current reactive sputtering is maintained at 1×10⁻⁵ to 3×10⁻⁵ torr, preferably 1.2×10⁻⁵ to 2.5×10⁻⁵ torr, preferably 1.5×10⁻⁵ to 2×10⁻⁵ torr, preferably 1.6'10⁻⁵ to 2×10⁻⁵ torr, preferably 1.7×10⁻⁵ torr. Other ranges are also possible. In some embodiments, a working pressure of the direct current reactive sputtering is maintained at 2×10⁻³ to 4×10⁻³ torr, preferably 2.2×10⁻³ to 3.8×10⁻³ torr, preferably 2.5×10⁻³ to 3.2×10⁻³ torr, preferably 2.6×10⁻³ to 3×10⁻³ torr, preferably 2.8×10⁻³ torr. Other ranges are also possible. The Ag nanoparticles present in the Ag nanoparticle decorated polymer substrate are in the form of a discontinuous film. In some embodiments, the average thickness of the discontinuous film is in a range of 20 to 200 nm, preferably 30 to 150 nm, preferably 40 to 100 nm, or even more preferably about 50 nm. Other ranges are also possible.

A method of preparing the tungsten trioxide (WO₃) nanoparticle-decorated polymer substrate is described. The method includes direct current reactive sputtering tungsten (W) onto the treated PC substrate in a gaseous mixture comprising oxygen to deposit WO₃ nanoparticles onto the surface of the treated PC substrate. In some embodiments, the direct current reactive sputtering is carried out at a power of 10 to 50 watts (W), preferably 15-45 W, preferably 20-40 W, preferably 25-35 W, and preferably 30 W for an appropriate amount of time. Other ranges are also possible. In some embodiments, the gaseous mixture including oxygen is introduced at a flow rate of 30 to 90 standard cubic centimeters per minute (sccm), preferably 30-80 sccm, preferably 30-70 sccm, preferably 30-60 sccm, preferably 30-50 sccm, preferably 30-40 sccm, preferably 30 sccm. Other ranges are also possible. The gaseous mixture further includes an inert gas. The inert gas is preferably Argon. Optionally, other inert gases, such as Helium, may be used as well. In some embodiments, a volume ratio of the oxygen to the inert gas present in the gaseous mixture is in a range of 5:1 to 1:5, or preferably 2:1 to 1:2. Other ranges are also possible. In some embodiments, a distance of a tungsten source to the treated PC substrate is in a range of 5 to 20 centimeters (cm), preferably 7-17 cm, preferably 8-15 cm, preferably 9-12 cm, preferably 10-12 cm, preferably 10 cm, during the direct current reactive sputtering tungsten. Other ranges are also possible. In some embodiments, a base pressure of the direct current reactive sputtering is maintained at 1×10⁻⁵ to 3×10⁻⁵ torr, preferably 1.2×10⁻⁵ to 2.5×10⁻⁵ torr, preferably 1.5×10⁻⁵ to 2×10⁻⁵ torr, preferably 1.6×10⁻⁵ to 2×10⁻⁵ torr, preferably 1.7×10⁻⁵ torr. Other ranges are also possible. In some embodiments, a working pressure of the direct current reactive sputtering is maintained at 2×10⁻³ to 4×10⁻³ torr, preferably 2.2×10⁻³ to 3.8×10⁻³ torr, preferably 2.5×10⁻³ to 3.2×10⁻³ torr, preferably 2.6×10⁻³ to 3×10⁻³ torr, preferably 2.8×10⁻³ torr. Other ranges are also possible. The WO₃ nanoparticles present in the WO₃ nanoparticle decorated polymer substrate are in the form of a film. In some embodiments, the average thickness of the film is in a range of 20 to 200 nm, preferably 30 to 150 nm, preferably 40 to 100 nm, or even more preferably about 50 nm. Other ranges are also possible.

### EXAMPLES

The following examples demonstrate a polymer-supported multifunctional metal/metal oxide surfaces as described herein. The examples are provided solely for illustration and are not to be construed as limitations of the present disclosure, as many variations thereof are possible without departing from the spirit and scope of the present disclosure.

### Example 1: Materials and Methods

Functional hydrophobic and hydrophilic surfaces were fabricated in a two-step process, as shown in FIG. 2A. In the first step, PC specimens were treated under a predesigned mask, whereas the same treated specimens were transferred to a sputtering chamber for functional metal or metal oxide depositions in the second step. Insets (i), (ii), and (iii) of FIG. 2A represents CCD images of pristine PC, treated PC, and metal/metal oxide-decorated treated PC, respectively. Small pieces of preferably, e.g., 2.5 cm×2.5 cm×1.6 mm were prepared from commercially available PC sheet (preferably e.g., 1 mm×1 mm×1.6 mm) and used as a starting substrate without any further functionalization. The commercial PC sheet has a thick cover on both sides to protect the surface. The top surface of the specimen was masked by removing a specific section of the cover. The substrates were immersed in a beaker full of 2-propanone (CH₃—CO—CH₃) from Sigma-Aldrich, as received, for 7 minutes at room temperature. The sample was washed copiously with deionized (DI) water, followed by the removal of the thick cover that was used as a mask. Therefore, the right side of the surface was treated, and the left side was left untreated because of the cover, as shown in FIG. 2B and FIG. 2C. As shown in FIG. 2A, a second mask was designed using duct tape to partially cover the treated and untreated surface. Circular Ag and W (5 cm in diameter, 3.18 mm in thickness, and 99.999% purity) targets were purchased from Matsurf and used as received without any modification. A sputtering coater (Nanomaster NSC3000, USA) was used to sputter metal and metal oxide layers on the masked specimen. The target-to-substrate distance was fixed at 10 cm. As for Ag sputtering, a direct current (DC, 30 W) gun was used to sputter the Ag from the target onto the specimen in a downward configuration. The base pressure and working pressure in the sputtering chamber were maintained at approximately 1.7×10⁻⁵ torr and 2.8×10⁻³ torr, respectively. The argon (Ar) flow rate in the chamber was kept at 30 SCCM during the deposition. A thickness-bound process was initiated, and the in-built thickness monitor was configured to 50 nm. Due to the second mask, half of the pristine PC and half of the treated PC were decorated with Ag, as shown in FIG. 2B.

In FIG. 2B, the dashed cross-hair guides one to isolate four sections, viz., the down-left corner: pristine PC, the down-right corner: treated PC, the top-left corner: Ag-decorated pristine PC and the top-right corner: Ag-decorated treated PC. As for metal oxide, WO₃ deposition, the Ag target was replaced with a tungsten (W) target, and the same DC gun of 30 W was used to sputter WO₃. In this case, the argon/oxygen flow rate in the chamber was kept at 30/30 SCCM during the deposition. A thickness-bound process was initiated, and the in-built thickness monitor was configured to 50 nm. The base pressure and working pressure in the sputtering chamber were maintained at approximately 1.7×10⁻⁵ torr and 2.8×10⁻³ torr, respectively. Similar to Ag decoration, half of the pristine PC and half of the treated PC were decorated with WO₃, as shown in FIG. 2C. In FIG. 2C, the dashed cross-hair guides one to isolate four sections for further characterization. Sections of pristine PC, treated PC, WO₃-decorated pristine PC, and WO₃-decorated treated PC were marked in the down-left corner, down-right corner, top-left corner, and top-right corner of FIG. 2C, respectively.

For a surface to be hydrophobic or hydrophilic, it is inevitable to investigate surface topography in detail. At the same time, the deposition of functional materials on top of such a special surface needs to be thoroughly examined. The surface topography and morphological characteristics of each specimen mentioned above were attentively recorded using a high-resolution FESEM (JEOL JSM6610LV, Japan). The elemental composition of functional materials and the substrate underneath were extracted using SEM-aided energy dispersion spectroscopy (EDS). Sessile drop tests were conducted to evaluate WCA using the WCA measurement system (DSA25, Denmark). An automatic dispensing system was utilized to generate drops of ˜4 μl on the specimen, and a computer-controlled imaging system was used to record the WCA of the fitted droplet.

FIGS. 2D to 2G show SEM micrographs of typical specimens under different conditions. High-resolution FESEM micrographs of corresponding specimens are depicted in detail in the following section. The pristine PC, Ag-decorated, and WO₃-decorated pristine PC were found to be smooth, as shown in the low-resolution SEM image in FIG. 2D. Insets (i)-(ii) of FIG. 2D represent typical SEM micrographs of Ag-decorated and WO₃-decorated pristine PC, respectively. However, further treatment of pristine PC yielded unique nanostructures, as shown in FIG. 2F and 2G.

FIG. 2E is a low-resolution SEM micrograph confirming the wide coverage of nanostructures all over the surface. Inset (i) of FIG. 2E shows a typical high-resolution SEM image of the same, showing nano-flowers-like structures on base nanostructures. In-depth examinations of such nanostructures have been elaborated in the later part of the text. Decoration of functional metal and metal oxide on such nanostructures is an emerging field of research for application-specific device fabrication.

FIG. 2F shows a low-resolution SEM image of Ag-decoration on a treated PC. Nano-flowers and base nanostructures were observed to be slightly covered by metal sputtering, as shown in inset (i) therein. Inset (i) of FIG. 2F represents a typical high-resolution micrograph of an Ag-decorated treated PC. In the case of metal oxide, such as WO₃ decoration on such treated PC, nano-flowers and base nanostructures were observed to be deeply covered, as shown in FIG. 2G. FIG. 2G shows a typical low-resolution SEM image of WO₃-decoration on a treated PC. A high-resolution SEM micrograph of the same is shown in inset (i) of FIG. 2G.

FIG. 3A shows a typical high-resolution FESEM micrograph of the treated PC. Two types of nanostructures were observed in such a scenario. Inset (i) of FIG. 3A shows isolated nano-flowers with very thin and elongated petals, and inset (ii) of FIG. 3A shows fine base nanostructures onto which nano-flowers were popped up as depicted in FIG. 3A. A zoon-in view (5 μm×5 μm) of an individual nano-flower as marked by the white square therein as shown in inset (i) of FIG. 3A. Conversely, a zoom-in view (3 μm×3 μm) of fine base nanostructures, as marked by the white square, was shown in inset (ii) of FIG. 3A. A 3D hawk-eye view of the nano-flower and fine base nanostructure, as shown in insets (i)-(ii), were depicted in inset (iii) as shown in FIG. 3B and inset (v) as shown in FIG. 3D, respectively. For example, an elongated petal was marked by the arrow in inset (iii) of FIG. 3A, as shown in FIG. 3B.

A line profile along the dashed line is shown in inset (i) of FIG. 3A was presented in inset (iv) as shown in FIG. 3C. The hills and dips, as shown in inset (iii) of FIG. 3A was found to vary from place to place. However, sharp spikes were observed at the top of such hills and dips. In the case of fine base nanostructures, hills and dips were not observed; instead, sharp spikes were noted, as shown in the inset (vi) as shown in FIG. 3E. Inset (vi) of FIG. 3A represents a line profile along the dashed line as shown in inset (ii) of FIG. 3A. As for hydrophobic and hydrophilic substrates, both chemical and topographical properties of the surface are critical to defining the wettability of the surface. In this context, elemental compositions were validated using SEM-aided EDS and corresponding EDS mapping, as shown in FIGS. 4A to 4D. FIG. 4A represents a site of interest in SEM-aided EDS and EDS mapping measurements. The EDS spectrum, as shown in inset (i) of FIG. 4A confirmed the presence of C and O at 0.277 eV (Kα) and 0.525 eV (Kα), respectively. EDS peaks of gold (Au) appeared due to gold coating. The distribution of constituent elements over the surface using EDS mapping was shown in insets (ii)-(iv), as depicted in FIGS. 4B to 4D. Insets (ii)-(iii) of FIGS. 4A show EDS mappings of elements C and O, respectively, whereas the overlay mapping of the SEM micrograph and EDS mapping of constituent elements were shown in inset (iv) of FIG. 4A, as depicted in FIG. 4D.

As mentioned above, the decoration of such nanostructures with functional metals and metal oxides is crucial, since the chemical and topographic properties of the surface at affected by the decoration. FIGS. 5A to 5E, 6A to 6G, 7A to 7G, and 8A to 8G demonstrate an in-depth investigation of an attempt to decorate a treated PC that consisted of nano-flowers and fine base nanostructures. FIG. 5A shows a typical high-resolution FESEM micrograph of an Ag-decorated treated PC. A zoom-in view (5 μm×5 μm) of an individual nano-flower decorated with Ag as marked by the white square therein as shown in inset (i) of FIG. 5A. The constituent petals of the nano-flowers were found to be decorated with Ag as well. As for fine base nanostructures, a zoom-in view (3 μm×3 μm), as marked by the white square therein, was shown in inset (ii) of FIG. 5A. Due to the Ag decoration, the fine base nanostructures were found to be more visible compared to those of treated PC. A 3D hawk-eye view of Ag-decorated nano-flower and that of fine base nanostructure as shown in insets (i)-(ii) of FIG. 5A were presented in inset (iii) and inset (v) of FIG. 5A, as shown in FIGS. 5B and 5D, respectively. White arrows in inset (iii) and inset (v) of FIG. 5A indicate typical Ag-decorated petal of nano-flower and that of fine base nanostructures, respectively. Line profiles along the dashed lines are shown in inset (i) and inset (ii) of FIG. 5A were presented in inset (iv) and inset (vi) of FIG. 5A, as shown in FIGS. 5C and 5E, respectively. The dimensions of hills and dips, as shown in inset (iv) of FIG. 5A were found to be quite narrow, along with sharp spikes atop. There were no such hills and dips observed in the case of Ag-decorated fine base nanostructures. A line profile along the dashed line, as shown in inset (ii) of FIG. 5A was presented in inset (vi), as depicted in FIG. 5E. The distribution of sharp spikes observed in Ag-decorated nano-flowers and that of fine base nanostructures was found to be homogenous. Such sharp spikes were speculated to be responsible for inducing higher wettability of the Ag-decorated surfaces.

Elemental compositions of Ag-decorated nano-flowers and those of Ag-decorated fine base nanostructures were validated using SEM-aided EDS and corresponding EDS mapping. FIG. 6A represents a site of interest comprising isolated nano-flowers and fine-base nanostructures. Within the site, two scans, one-where the entire area and other one-a dot on Ag-decorated petal were recorded. In both scans, the EDS spectra as shown in insets (i) and inset (ii) of FIG. 6A confirmed the presence of Ag, C, and O at 2.984 eV (Lα), 0.277 eV (Kα), and 0.525 eV (Kα), as shown in FIGS. 6B to 6D, respectively. The weight percentages of the constituent elements were amended within the insets. EDS mappings for elements C, Ag, and O were shown in insets (iii)-(v), as shown in FIGS. 6D to 6F, respectively. An overlay mapping of SEM micrograph and EDS mapping of constituent elements was shown in the inset (vi) of FIG. 5B, as depicted in FIG. 6G.

A typical high-resolution FESEM micrograph of WO₃-decorated treated PC is shown in FIG. 7A. With reference to those in Ag-decorated treated PC, one could note that the nano-flowers and fine base nanostructures were nearly buried in the case of WO₃ decoration. A zoom-in view (7 μm×7 μm) of treated PC comprising WO₃-decorated fine base nanostructures was shown in inset (i) of FIG. 7A. On the other hand, A zoon-in view (15 μm×15 μm) of treated PC, including isolated nano-flowers decorated with WO₃ as marked by the white square therein, as shown in inset (ii) of FIG. 7A. Unlike those observed in Ag-decorated nano-flowers and those of fine base nanostructures, the constituent petals and fine base nanostructures were not visible. 3D hawk-eye views of WO₃-decorated fine base nanostructure and that of nano-flower as shown in insets (i)-(ii) were presented in inset (iii) and inset (v) of FIG. 7A, as depicted in FIGS. 7B and 7D, respectively. The white arrows in inset (iii) and inset (v) of FIG. 7A indicates typical WO₃-decorated fine base nanostructures and those of nano-flowers, respectively. The line profile along the dashed line shown in inset (i) of FIG. 6A was presented in inset (iv), as depicted in FIG. 7C. Unlike those of Ag-decorated fine base nanostructures, broadened hills and dips were observed, as shown in inset (iv) of FIG. 7A. The dimension of hills and dips indeed indicates the size of WO₃ clusters deposited atop them. In the case of WO₃-decorated nano-flowers, the dimensions of hills and dips, as shown in inset (iv) of FIG. 7A was found to be quite broad, which indicated the disappearance of nano-flowers. Such broadened dimensions of hills and dips were speculated to be responsible for reducing wettability in the case of WO₃-decorated surfaces.

Elemental compositions of WO₃-decorated treated PC comprised of nano-flowers and fine base nanostructures were validated using SEM-aided EDS and corresponding EDS mapping. FIG. 8A represents a site of interest wherein two scans, one-where the entire area and other one-where a dot on nano-flower were recorded. In both scans, the EDS spectra as shown in insets (i) and inset (ii) of FIG. 8A confirmed the presence of W, C, and O at 1.774 eV (M), 0.277 eV (Kα), and 0.525 eV (Kα), respectively, as depicted in FIGS. 8B and 8C. The weight percentages of the constituent elements were amended within the insets. EDS mappings for elements C, O, and W were shown in insets (iii)-(v), respectively, as depicted in FIGS. 8D to 8F. An overlay mapping of the SEM micrograph and EDS mapping of constituent elements was shown in the inset (vi) of FIG. 8A, as depicted in FIG. 8C.

A set of sessile drop tests was carried out to understand the wetting characteristics of pristine PC, treated PC, and those of Ag- and WO₃-decorated pristine and treated PC, as shown in FIG. 9A. WCA is the measure of an indication of whether the surface is hydrophobic or hydrophilic. DI water was used as the reference liquid, and the volume was controlled by an automatic dispenser. The wetting characteristics of Ag-decorated glass substrates and those of pristine PC have been shown as references. FIG. 9A represents water droplet images of Ag-decorated glass substrate corresponding to an average WCA of 43.5°, whereas the average WCA for glass substrate without decoration was found to be 70.2° as shown in the inset of FIG. 9A. The average WCA dropped nearly 40% after the decoration of Ag. In the case of pristine PC, as shown in FIG. 9B, the average WC for Ag-decorated pristine PC was found to be 42.6°, whereas the average WCA for pristine PC without decoration was noted to be 77.6° as shown in the inset of FIG. 9B. The average WCA drop for Ag-decorated pristine PC was found to be almost similar to that of Ag-decorated glass substrate. However, once the pristine PC was treated, the surface became hydrophobic, and the average WCA was found to be as high as 110.5°. FIG. 9C shows water droplet images of Ag-decorated treated PC corresponding to an average WCA of 106.6°, whereas the average WCA for treated PC without decoration was found to be 110.5° as shown in the inset of FIG. 9C. Interestingly, it was noted that Ag-decorated treated PC remained hydrophobic, and the average WCA dropped nearly 4% only after the decoration. In the case of WO₃-decorated pristine PC, the surface of the same became hydrophilic, as shown in FIG. 9D. FIG. 9D shows a water droplet image of a WO₃-decorated pristine PC corresponding to an average WCA of 13.6°, whereas the average WCA for pristine PC without decoration was found to be 77.6° as shown in the inset of FIG. 9B. The average WCA dropped nearly 64% after the decoration of pristine PCs with WO₃. Similarly, the WO₃-decorated treated PC became hydrophilic, although the treated PC was found to be hydrophobic. FIG. 9E shows water droplet images of WO₃-decorated treated PC corresponding to an average WCA of 11.7°, whereas the average WCA for treated PC without decoration was found to be 110.5° as shown in the inset of FIG. 9C. WO₃-decorated treated PC turned hydrophilic, and the average WCA dropped nearly 99% after the decoration. FIG. 9F shows a representative bar graph summarizing an average WCA for glass substrates, pristine PC, treated PC, and Ag-and WO₃ decorations of the same substrates.

The wetting characteristics of an active surface are demonstrated by the Wenzel model or the Cassie-Baxter model, or a combination of these two models. The Wenzel model illustrates the scenario where droplets penetrate the nanostructures underneath, leading to high adhesive forces. On the other hand, the Cassie-Baxter Model illustrates a scenario where droplets cannot penetrate the nanostructures underneath them, trapping air beneath them. However, most of the superhydrophobic surfaces utilize dual-scale roughness where micro-and/or nanostructures are furnished with further nanoscale roughness. The transition from Cassie-Baxter states to Wenzel states has been acknowledged to turn the hydrophobic surface hydrophilic. The treated PC consisted of nano-flowers and fine-base nanostructures. High-resolution FESEM investigation revealed elongated petals within the nano-flowers, as demonstrated in FIG. 3A. The petals of the nano-flowers satisfied the Cassie-Baxter model indicating fine nanoscale roughness on the top of the nano-flowers. Therefore, the average WCA was recorded as high as 110.5°. In the case of Ag-decorated treated PC, the petals of nano-flowers were observed to hold the nanoscale roughness as demonstrated in FIG. 5A. Henceforth, the average WCA of 106.6° was recorded at Ag-decorated treated PC. As explained in the high-resolution FESEM investigation in FIG. 7A, the WO₃-decorated treated PC failed to hold nanoscale roughness due to covering the nano-flowers, including petals and fine base nanostructures. In this context, it was noted that the hydrophobic characteristics of treated PC drastically changed to a hydrophilic state.

To summarize, commercially available PC was treated in a simple and two-step process to develop polymer-supported multifunctional surfaces. The treated PC exhibited hydrophobic characteristics with an average WCA as high as 110.5°. Further decoration with functional metals such as Ag was carried out in the 2^{nd} step, and interestingly, wetting characteristics remained high with an average WCA as high as 106.6°. High-resolution FESEM investigations confirmed the formation of nano-flowers with a coverage density of 9.29×10⁶/cm² on the top of fine base nanostructures. Petals of nano-flower functioned as nanoscale nanostructures on the top of nano-flowers. Therefore, the active surface remained hydrophobic according to the Cassie-Baxter model. When the same treated PC was decorated with functional metal oxide, such as WO₃, the active surface became hydrophilic with an average WCA as low as 11.7°. High-resolution FESEM investigations revealed that the nano-flowers, along with petals and fine base nanostructures, got fully covered with WO₃ upon decoration. Therefore, it was shown that the structural changes at the nanoscale facilitated to achieve hydrophilic characteristics of WO₃-decorated treated PC. Sessile drop tests were carried out to record average WCA and to understand the wetting characteristics of pristine PC, treated PC, and Ag-and WO₃-decorated pristine and treated PC.

Numerous modifications and variations of the present disclosure are possible in light of the above teachings. It is therefore to be understood that within the scope of the appended claims, the invention may be practiced otherwise than as specifically described herein.

1. A silver (Ag) nanoparticle decorated polymer substrate, comprising:
a treated polycarbonate (PC) substrate;
wherein the treated PC substrate has a roughened surface comprising polycarbonate structures in the form of circular shaped base structures covering a surface of the treated PC substrate, and nano-flowers directly grown on the circular shaped base structures, and wherein the nano-flowers have elongated petals extending therefrom;
wherein the circular shaped base structures have an average diameter of 2 to 10 micrometers (μm);
wherein an average width of the elongated petals of the nano-flowers is in a range of 60 to 400 nanometers (nm); and
a plurality of silver nanoparticles homogeneously disposed on the roughened surface of the treated PC substrate;
wherein an average wetting contact angle (WCA) of water on a surface of the silver decorated polymer substrate is in a range of about 105 to 108 degrees (°).

2. The Ag nanoparticle decorated polymer substrate of claim 1, wherein the WCA of water on a surface of the treated PC substrate is in a range of 109 to 112°.

3. The Ag nanoparticle decorated polymer substrate of claim 1, wherein the average width of the elongated petals of the nano-flowers is in a range of 150 to 250 nm.

4. The Ag nanoparticle decorated polymer substrate of claim 1, wherein the plurality of silver nanoparticles have an average particle size in a range of 5 to 50 nm.

5. The Ag nanoparticle decorated polymer substrate of claim 1, wherein the WCA of water on the surface of the silver decorated polymer substrate is about 106.6°.

6. A method of making the silver (Ag) nanoparticle decorated polymer substrate of claim 1, comprising:
direct current reactive sputtering silver (Ag) onto the treated PC in an inert gas to deposit Ag nanoparticles onto the surface of the treated PC substrate;
wherein the Ag nanoparticles present in the Ag nanoparticle decorated polymer substrate are in the form of a discontinuous film, and wherein an average thickness of the discontinuous film is about 50 nm.

7. The method of claim 6, wherein the direct current reactive sputtering is carried out at a power of 10 to 50 watts (W) for an appropriate amount of time and the inert gas is introduced at a flow rate of 20 to 40 standard cubic centimeters per minute (sccm).

8. The method of claim 6, wherein a distance of a silver source to the treated PC substrate is in a range of 5 to 20 centimeters (cm) during the direct current reactive sputtering silver.

9. The method of claim 6, wherein a base pressure of the direct current reactive sputtering is maintained at 1×10⁻⁵ to 3×10⁻⁵ torr, and a working pressure of the direct current reactive sputtering is maintained at 2×10⁻³ to 4×10⁻³ torr.

10. The method of claim 6, further comprising:
preparing the treated PC substrate by:
immersing an untreated polycarbonate (PC) substrate in acetone for an appropriate amount of time; and
removing the untreated PC substrate from the acetone, washing and drying to form the treated PC substrate;
wherein the treated PC substrate has a roughened surface containing polycarbonate structures.

11. The method of claim 10, wherein the PC substrate is a bisphenol A polycarbonate, and wherein an average wetting contact angle of water on a surface of the bisphenol A polycarbonate is in a range of 76 to 79°.

12. A tungsten oxide (WO₃) nanoparticle decorated polymer substrate, comprising:
a treated polycarbonate (PC) substrate;
wherein the treated PC substrate has a roughened surface comprising polycarbonate structures in the form of circular shaped base structures covering a surface of the treated PC substrate, and nano-flowers directly grown on the circular shaped base structures, and wherein the nano-flowers have elongated petals extending therefrom;
wherein the circular shaped base structures have an average diameter of 2 to 10 micrometers (μm);
wherein an average width of the elongated petals of the nano-flowers is in a range of 60 to 400 nm; and
a plurality of WO₃ nanoparticles disposed on the surface of the treated PC substrate;
wherein an average wetting contact angle (WCA) of water on a surface of the WO₃ nanoparticle decorated polymer substrate is about 10 to 13°.

13. The WO₃ nanoparticle decorated polymer substrate of claim 12, wherein the plurality of WO₃ nanoparticles have an average particle size in a range of 10 to 50 nanometers (nm).

14. The WO₃ nanoparticle decorated polymer substrate of claim 12, having a cauliflower-shaped convex-concave surface, and wherein an average distance between the highest points of two adjacent convex portions on the cauliflower-shaped convex-concave surface is in a range of 300 to 900 nm.

15. The WO₃ nanoparticle decorated polymer substrate of claim 12, wherein the WCA of water on the surface of the WO₃ nanoparticle decorated polymer substrate is about 11.7°.

16. A method of making the tungsten trioxide (WO₃) nanoparticle decorated polymer substrate of claim 12, comprising:
direct current reactive sputtering tungsten (W) onto the treated PC substrate in a gaseous mixture comprising oxygen to deposit WO₃ nanoparticles onto the surface of the treated PC substrate;
wherein the WO₃ nanoparticles present in the WO₃ nanoparticle decorated polymer substrate are in the form of a film, and wherein an average thickness of the film is about 50 nm.

17. The method of claim 16, wherein the direct current reactive sputtering is carried out at a power of 10 to 50 watts (W) for an appropriate amount of time and the gaseous mixture comprising oxygen is introduced at a flow rate of 30 to 90 standard cubic centimeters per minute (sccm).

18. The method of claim 16, wherein the gaseous mixture further comprises an inert gas, and wherein a volume ratio of the oxygen to the inert gas present in the gaseous mixture is in a range of 2:1 to 1:2.

19. The method of claim 16, wherein a distance of a tungsten source to the treated PC substrate is in a range of 5 to 20 centimeters (cm) during the direct current reactive sputtering tungsten.

20. The method of claim 16, wherein a base pressure of the direct current reactive sputtering is maintained at 1×10⁻⁵ to 3×10⁻⁵ torr, and a working pressure of the direct current reactive sputtering is maintained at 2×10⁻³ to 4×10⁻³ torr.
